(19) United States
(12) Patent Application Publication
(10) Pub. No.: US 2006/0050898 A1
(43) Pub. Date: Mar. 9, 2006

(54) Audio signal processing apparatus and method

(75) Inventors: Yuji Yamada, Tokyo (JP); Koyuru Okimoto, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Sony Corporation, Tokyo (JP)

(21) Appl. No.: 11/212,734

(22) Filed: Aug. 29, 2005

(30) Foreign Application Priority Data
Sep. 8, 2004 (JP) 2004-260397

(51) Int. Cl. H03G 3/00; H03G 5/00

(52) U.S. Cl. 381/104; 381/102; 381/98

(57) ABSTRACT

An audio signal processing apparatus includes a dividing unit dividing each of two audio signals into a plurality of frequency bands, a level comparing unit determining a level ratio or level difference between the two audio signals in each of the plurality of frequency bands divided by the dividing unit, and an output control unit controlling an output of the dividing unit according to the level ratio or level difference determined by the level comparing unit.

### CROSS REFERENCES TO RELATED APPLICATIONS

The present invention contains subject matter related to Japanese Patent Application JP 2004-260397 filed in the Japanese Patent Office on Sep. 8, 2004, the entire contents of which are incorporated herein by reference.

### BACKGROUND OF THE INVENTION

1. Field of the Invention

The present invention relates to an audio signal processing apparatus and method for separating an audio signal of a specific sound source from input time-series audio signals of two channels including audio signals from a plurality of sound sources.

2. Description of the Related Art

In general, two-channel (right- and left-channel) stereo audio signals recorded in discs, compact discs, etc., include audio signals from a plurality of sound sources. Such stereo audio signals are often recorded into the individual channels with level differences so that when the stereo audio signals are reproduced by two speakers, sound images of the plurality of sound sources are localized between the speakers.

For example, signals S1 to S5 of five sound sources 1 to 5 are recorded as left- and right-channel audio signals SL and SR as follows:

ti SL=S1+0.9S2+0.7S3+0.4S4
SR=S5+0.4S2+0.7S3+0.9S4

In this case, the signals S1 to S5 of the sound sources 1 to 5 are mixed in the left and right channels with level differences, and audio signals of the individual channels are produced.

When the stereo audio signals in which the signals S1 to S5 of the sound sources 1 to 5 are distributed to the right and left channels with level differences are reproduced by, for example, two speakers 1L and 1R shown in FIG. 19, a listener 2 can perceive sound images A, B, C, D, and E corresponding to the sound sources 1, 2, 3, 4, and 5. As is also known in the art, the sound images A, B, C, D, and E are localized between the speakers 1L and 1R.

As shown in FIG. 20, when the listener 2 who wears a headphone device 3 reproduces the stereo audio signals of the right and left channels from a right speaker unit 3R and a left speaker unit 3L of the headphone device 3, the listener 2 can perceive sound images A, B, C, D, and E corresponding to the sound sources 1, 2, 3, 4, and 5 inside the listener's head.

A mechanism for separating and outputting only an audio signal of a specific sound source from general two-channel stereo audio signals allows for extraction of only the sound of a vocalist or only the sound of a specific sound source, such as a violin, and can be used for various applications.

One known method for separating and outputting an audio signal of a specific sound source from two-channel stereo audio signals is shown in FIG. 21 (see PCT Japanese Translation Patent Publication No. 2003-515771). In this method, band-pass filters each for extracting a high frequency energy component of an audio signal of a desired sound source are provided for the number of desired sound sources to be separated, and the band-pass filters are used to separate the audio signals of the desired sound sources from two-channel stereo audio signals.

In the example shown in FIG. 21, an audio signal Sa of a sound source a and an audio signal Sb of a sound source b are separated from a left-channel audio signal SL, and an audio signal Sc of a sound source c and an audio signal Sd of a sound source d are separated from a right-channel audio signal SR. A sound source separation processing circuit 7 includes four band-pass filters 3 to 6 corresponding to the sound sources a to d.

As shown in FIG. 21, the left-channel audio signal SL is supplied to the band-pass filter 3 to extract a high frequency energy component constituting the sound source a of the audio signal Sa, and is also supplied to the band-pass filter 4 to extract a high frequency energy component constituting the sound source b of the audio signal Sb. The audio signals Sa and Sb are obtained from the band-pass filters 3 and 4, respectively.

The right-channel audio signal SR is supplied to the band-pass filter 5 to extract a high frequency energy component constituting the sound source c of the audio signal Sc, and is also supplied to the band-pass filter 6 to extract a high frequency energy component constituting the sound source d of the audio signal Sd. The audio signals Sc and Sd are obtained from the band-pass filters 5 and 6, respectively.

### SUMMARY OF THE INVENTION

However, the method shown in FIG. 21 has the following problem. Sound sources having center frequencies in different frequency bands, such as a bass guitar and a cymbal, can be separated to some extent; however, it is difficult to separate signals of sound sources sharing many frequency bands, including the waves that exist in the overlapping frequency bands and the harmonics of the sound sources outside the frequency ranges selected by the band-pass filters.

It is therefore desirable to provide an audio signal processing apparatus and method for separating an audio signal of a specific sound source from audio signals of two channels including audio signals from a plurality of sound sources.

An audio signal processing apparatus according to an embodiment of the present invention includes the following elements. Dividing means divides each of two audio signals into a plurality of frequency bands. Level comparing means determines a level ratio or level difference between the two audio signals in each of the plurality of frequency bands divided by the dividing means. Output control means controls an output of the dividing means according to the level ratio or level difference determined by the level comparing means.

According to an embodiment of the present invention, a characteristic that audio signals of sound sources are mixed in two audio signals by a predetermined level ratio or level difference is used. In this case, each of the two audio signals is divided into a plurality of frequency bands. The level ratio or level difference between the two audio signals in each of the frequency bands is determined, and a signal component in a frequency band that provides a predetermined level ratio or level difference or about the predetermined level ratio or level difference is extracted from at least one of the two audio signals.

If the predetermined level ratio or level difference is set to the level ratio or level difference by which an audio signal of a specific sound source is mixed in the two audio signals, the frequency component constituting the audio signal of the specific sound source is extracted from at least one of at least two audio signals. Thus, an audio signal of a specific sound source is extracted.

An audio signal processing apparatus according to another embodiment of the present invention includes the following elements. First transform means transforms a first time-series audio signal of two time-series audio signals into a first frequency-domain signal. Second transform means transforms a second time-series audio signal of the two time-series audio signals into a second frequency-domain signal. Level determining means determines a level ratio or level difference between a frequency spectrum of the first frequency-domain signal obtained from the first transform means and a frequency spectrum of the second frequency-domain signal obtained from the second transform means. Output control means controls and outputs a level of the frequency spectrum obtained from at least one of the first transform means and the second transform means based on the level ratio or level difference determined by the level determining means.

According to an embodiment of the present invention, two time-series audio signals are individually transformed by first and second transform means into frequency-domain signals each having a plurality of frequency spectral components.

The level ratio or level difference between the frequency spectrum obtained from the first transform means and the frequency spectrum obtained from the second transform means is determined. Based on the determined level ratio or level difference, the level of the frequency spectrum obtained from at least one of the first transform means and the second transform means is controlled, and the frequency component that provides a predetermined level ratio or level difference or about the predetermined level ratio or level difference is extracted and output.

If the predetermined level ratio or level difference is set to the level ratio or level difference by which an audio signal of a specific sound source is mixed in the two audio signals, frequency-domain components constituting the audio signal of the specific sound source are extracted from at least one of at least two audio signals. Thus, an audio signal of a specific sound source is extracted.

According to an embodiment of the present invention, the audio signal processing apparatus further includes phase difference determining means for determining a phase difference between a frequency spectrum of the first frequency-domain signal obtained from the first transform means and a frequency spectrum of the second frequency-domain signal obtained from the second transform means, and the output control means controls and outputs a level of the frequency spectrum obtained from at least one of the first transform means and the second transform means based on the level ratio or level difference determined by the level determining means and the phase difference determined by the phase difference determining means.

According to an embodiment of the present invention, two time-series audio signals are individually transformed by first and second transform means into frequency-domain signals each having a plurality of frequency spectral components.

The phase difference between the frequency spectrum obtained from the first transform means and the frequency spectrum obtained from the second transform means is determined. Based on the determined phase difference, the level of the frequency spectrum obtained from at least one of the first transform means and the second transform means is controlled, and the frequency component that provides a predetermined phase difference or about the predetermined phase difference is extracted and output.

If the predetermined phase difference is set to the phase difference by which an audio signal of a specific sound source is mixed in the two audio signals, frequency-domain components constituting the audio signal of the specific sound source are extracted from at least one of at least two audio signals. Thus, an audio signal of a specific sound source is extracted.

According to an embodiment of the present invention, therefore, an audio signal of a sound source that is mixed in two audio signals by a predetermined level ratio or level difference or by a predetermined phase difference can be separated from at least one of the two audio signals.

### BRIEF DESCRIPTION OF THE DRAWINGS

FIG. 1 is a block diagram of an audio signal processing apparatus according to a first embodiment of the present invention;

FIG. 2 is a block diagram of a frequency spectrum comparison processor in the audio signal processing apparatus shown in FIG. 1;

FIG. 3 is a block diagram of a frequency spectrum control processor in the audio signal processing apparatus shown in FIG. 1;

FIGS. 4A to 4E are diagrams showing functions used in a multiplication coefficient generator in the frequency spectrum control processor;

FIG. 5 is a block diagram of an audio signal processing apparatus according to a second embodiment of the present invention;

FIG. 6 is a block diagram of a frequency spectrum comparison processor and a frequency spectrum control processor in the audio signal processing apparatus shown in FIG. 5;

FIG. 7 is a block diagram of an audio signal processing apparatus according to a third embodiment of the present invention;

FIGS. 8A and 8B are diagrams showing functions used in multiplication coefficient generators in the audio signal processing apparatus shown in FIG. 7;

FIG. 9 is a block diagram of an audio signal processing apparatus according to a fourth embodiment of the present invention;

FIG. 10 is a block diagram of an audio signal processing apparatus according to a fifth embodiment of the present invention;

FIG. 11 is a block diagram of an audio signal processing apparatus according to a sixth embodiment of the present invention;

FIG. 12 is a block diagram of a frequency spectrum comparison processor and a frequency spectrum control processor in the audio signal processing apparatus shown in FIG. 11;

FIGS. 13A to 13E are diagrams showing functions used in multiplication coefficient generators in the frequency spectrum control processor shown in FIG. 12;

FIG. 14 is a block diagram of an audio signal processing apparatus according to a seventh embodiment of the present invention;

FIG. 15 is a diagram showing segmentation of data in an audio signal processing apparatus according to an eighth embodiment of the present invention;

FIG. 16 is a diagram showing segmentation of data in the audio signal processing apparatus according to the eighth embodiment of the present invention;

FIG. 17 is a diagram showing segmentation of data in an audio signal processing apparatus according to a ninth embodiment of the present invention;

FIG. 18 is a diagram showing segmentation of data in the audio signal processing apparatus according to the ninth embodiment of the present invention;

FIG. 19 is a diagram showing auditory localization of two-channel signals from a plurality of sound sources;

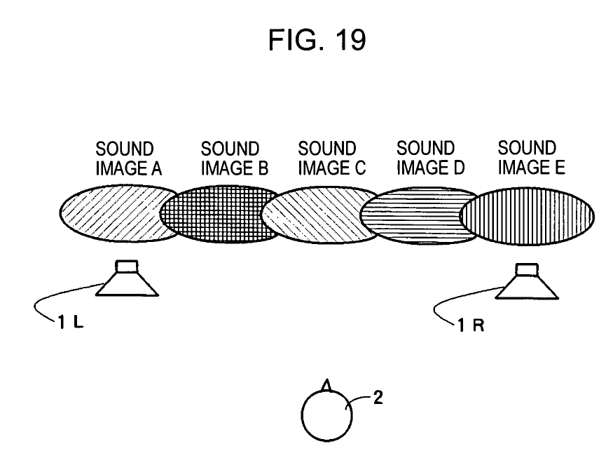

FIG. 20 is a diagram showing auditory localization of two-channel signals from a plurality of sound sources; and

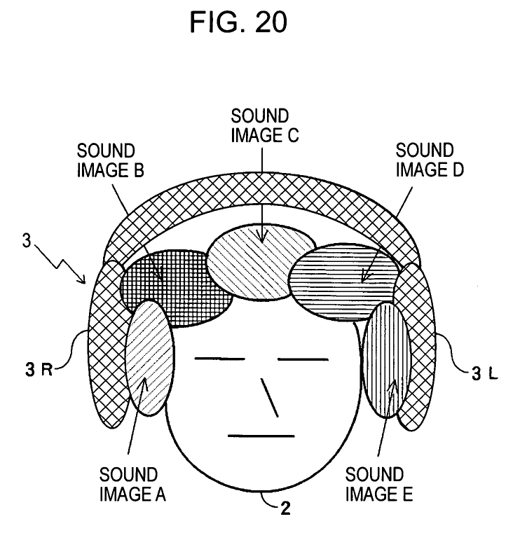

FIG. 21 is a block diagram of an apparatus of the related art for separating an audio signal of a specific sound source.

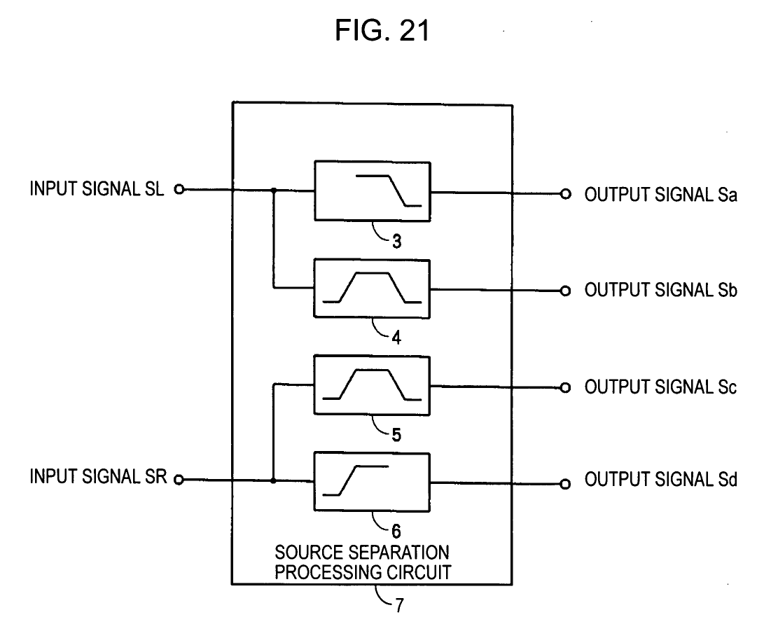

### DESCRIPTION OF THE PREFERRED EMBODIMENTS

An audio signal processing apparatus and method according to embodiments of the present invention will be described hereinbelow with reference to the drawings.

In the following description, a sound source is separated from stereo audio signals including a left-channel audio signal SL and a right-channel audio signal SR.

For example, audio signals S1 to S5 from sound sources 1 to 5 are distributed in the left-channel audio signal SL and the right-channel audio signal SR with level differences by the following ratio defined in Eqs. (1) and (2):
SL=S1+0.9S2+0.7S3+0.4S4 Eq. (1)
SR=S5+0.4S2+0.7S3+0.9S4 Eq. (2)

Comparing Eqs. (1) and (2), the audio signals S1 to S5 of the sound sources 1 to 5 are distributed in the left-channel audio signal SL and the right-channel audio signal SR with the above-described level differences. Thus, the original sound sources can be separated by re-distributing the sound sources from the left-channel audio signal SL and/or the right-channel audio signal SR according to the distribution ratio.

In the following embodiments, a characteristic that sound sources generally have different spectral components is used, and each of right- and left-channel stereo audio signals is divided in the frequency domain by high-resolution fast Fourier transform (FFT) into multiple frequency spectral components. Then, the level ratio or level difference between the frequency spectral components in the audio signal of each channel is determined, and a frequency spectral component having the level ratio or level difference corresponding to the distribution ratio defined in Eqs. (1) and (2) by which the audio signal of a desired sound source is distributed is detected, and the detected frequency spectral component is separated. Therefore, the sound source can be separated with less interference from other sound sources.

### First Embodiment

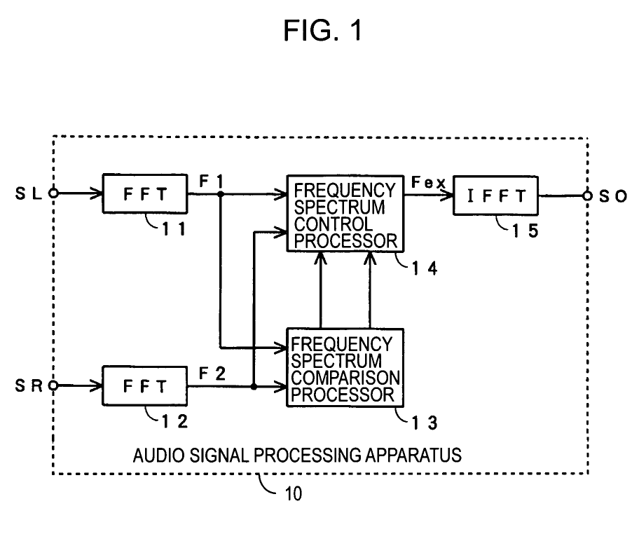

FIG. 1 is a block diagram of an audio signal processing apparatus 10 according to a first embodiment of the present invention. A left-channel audio signal SL of two-channel stereo signals is supplied to an FFT unit 11 serving as an orthogonal transformer. When the signal SL is an analog signal, the signal SL is converted into a digital signal, and is then subjected to FFT processing to transform the time-series audio signal into frequency-domain data. When the signal SL is a digital signal, it is not necessary for the FFT unit 11 to perform analog-digital conversion.

A right-channel audio signal SR of the two-channel stereo signals is supplied to an FFT unit 12 serving as an orthogonal transformer. When the signal SR is an analog signal, the signal SR is converted into a digital signal, and is then subjected to FFT processing to transform the time-series audio signal into frequency-domain data. When the signal SR is a digital signal, it is not necessary for the FFT unit 12 to perform analog-digital conversion.

The FFT units 11 and 12 have a similar structure, and divide the time-series signals SL and SR into frequency spectral components having a plurality of different frequencies, respectively. The number of frequencies divided to produce frequency spectra depends on the accuracy of sound source separation, and is, for example, 500 or greater, preferably, 4000 or greater. The number of frequencies depends on the number of points used in the FFT units 11 and 12.

Frequency spectra F1 and F2 output from the FFT units 11 and 12 are supplied to a frequency spectrum comparison processor 13 and a frequency spectrum control processor 14.

The frequency spectrum comparison processor 13 determines level ratios of the frequency spectral components F1 and F2 from the FFT units 11 and 12 at the same frequency, and outputs the level ratios to the frequency spectrum control processor 14. The level ratios are represented as level differences when levels are logarithmically expressed in decibels (dB).

The frequency spectrum control processor 14 extracts only a frequency spectral component having a predetermined level ratio from the output of at least one of the FFT units 11 and 12 based on the level ratio information from the frequency spectrum comparison processor 13, and outputs an extraction output Fex to an inverse FFT unit 15. In the example shown in FIG. 1, the frequency spectrum control processor 14 extracts a frequency spectral component having a predetermined level ratio from the outputs of both the FFT units 11 and 12, and outputs it as the extraction output Fex to the inverse FFT unit 15.

In the frequency spectrum control processor 14, a user presets which level ratio of frequency spectral component to extract depending on the sound source to be separated. Therefore, the frequency spectrum control processor 14 extracts only the frequency spectral component of the audio signal of the sound source that is distributed to the right and left channels by the level ratio set by the user for separation.

The inverse FFT unit 15 transforms the extracted frequency spectral component Fex output from the frequency spectrum control processor 14 into the original time-series signal, and the resulting signal is output as an audio signal SO of the desired sound source to be separated by the user. In order to output an analog audio signal, a digital-to-analog (D/A) converter is provided at the output side of the inverse FFT unit 15 to convert the signal into an analog audio signal. The same applies to the following embodiments.

The structure of the frequency spectrum comparison processor 13 will be described hereinbelow.

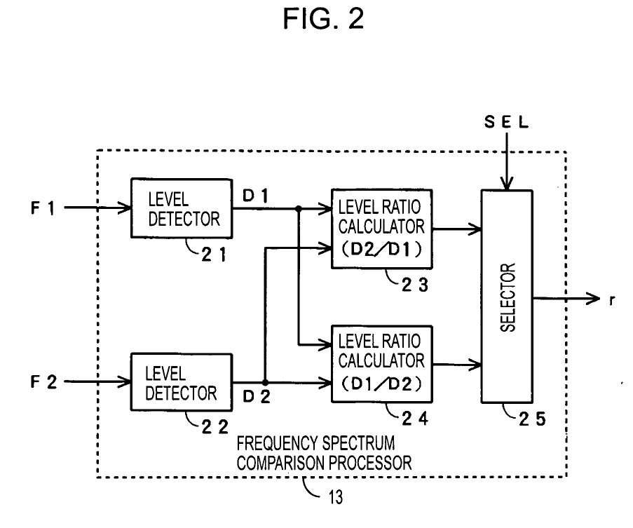

The frequency spectrum comparison processor 13 functionally has a structure shown in FIG. 2. The frequency spectrum comparison processor 13 includes level detectors 21 and 22, level ratio calculators 23 and 24, and a selector 25.

The level detector 21 detects the level of frequency components in the frequency spectral component F1 from the FFT unit 11, and outputs the detected level D1. The level detector 22 detects the level of frequency components in the frequency spectral component F2 from the FFT unit 12, and outputs the detected level D2. In order to determine the level of each frequency spectrum, an amplitude spectrum is detected, by way of example. A power spectrum may be detected to determine the level of each frequency spectrum.

The level ratio calculator 23 determines the ratio D2/D1. The level ratio calculator 24 determines the inverse, i.e., the ratio D1/D2. The level ratios determined by the level ratio calculators 23 and 24 are supplied to the selector 25, and one of the level ratios is extracted as an output level ratio r from the selector 25.

The selector 25 receives a selection control signal SEL for controlling selection of the output of either the level ratio calculator 23 or 24 depending on the sound source to be separated by the user and the level ratio of this sound source. The output level ratio r obtained from the selector 25 is supplied to the frequency spectrum control processor 14.

The level ratio of the sound source to be separated, which is used by the frequency spectrum control processor 14, has a value constantly satisfying the level ratio ≦1, by way of example. That is, the level ratio r input to the frequency spectrum control processor 14 is determined by dividing the level of a low-level frequency spectrum by the level of a high-level frequency spectrum.

Therefore, the frequency spectrum control processor 14 uses the level ratio output from the level ratio calculator 23 in order to separate a signal of a sound source that is distributed in the left-channel audio signal SL by a higher ratio, and uses the level ratio output from the level ratio calculator 24 in order to separate a signal of a sound source that is distributed in the right-channel audio signal SR by a higher ratio.

For example, it is assumed that distribution ratios PR and PL by which signals are distributed to the right and left channels are set by the user as level ratios of the sound source to be separated, where PL and PR are 1 or lower. If the distribution ratios PL and PR satisfy PR/PL ≦1, the selection control signal SEL is set as a selection control signal for controlling the selector 25 to select the output (D2/D1) of the level ratio calculator 23 as the output level ratio r. If the distribution ratios PL and PR satisfy PR/PL >1, the selection control signal SEL is set as a selection control signal for controlling the selector 25 to select the output (D1/D2) of the level ratio calculator 24 as the output level ratio r.

If the distribution ratios PL and PR set by the user are equal to each other, i.e., level ratio r=1, the selector 25 can select either the output of the level ratio calculator 23 or the output of the level ratio calculator 24.

The structure of the frequency spectrum control processor 14 will be described hereinbelow.

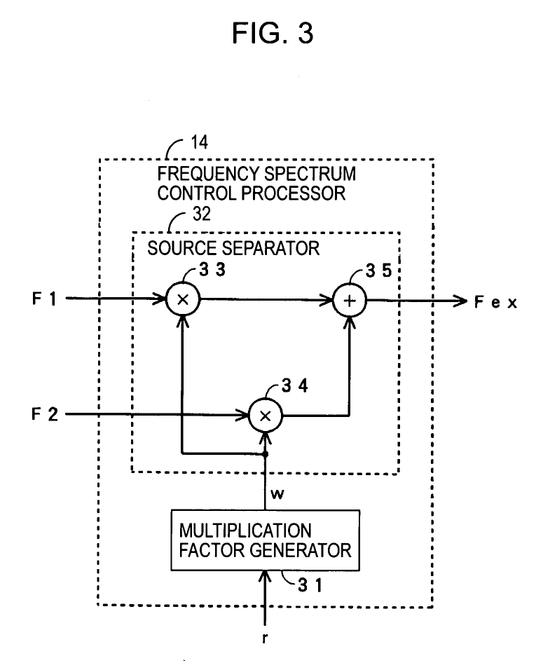

The frequency spectrum control processor 14 functionally has a structure shown in FIG. 3. The frequency spectrum control processor 14 includes a multiplication factor generator 31 and a source separator 32. The source separator 32 includes multipliers 33 and 34, and an adder 35.

The multiplier 33 receives the frequency spectral components from the FFT unit 11 and a multiplication factor w from the multiplication factor generator 31, and supplies the result of multiplication of the frequency spectral components and the multiplication factor w to the adder 35. The multiplier 34 receives the frequency spectral components from the FFT unit 12 and the multiplication factor w from the multiplication factor generator 31, and supplies the result of multiplication of the frequency spectral components and the multiplication factor w to the adder 35. An output of the adder 35 corresponds to the output Fex of the frequency spectrum control processor 14.

The multiplication factor generator 31 receives the output level ratio r from the selector 25 in the frequency spectrum comparison processor 13, and generates a multiplication factor w corresponding to the level ratio r. The multiplication factor generator 31 may be a function generating circuit for generating a function with respect to the multiplication factor w, wherein the level ratio r is a variable. The function used in the multiplication factor generator 31 depends on the distribution ratios PL and PR set by the user depending on the sound source to be separated.

Since the level ratio r supplied to the multiplication factor generator 31 changes in units of frequency components of a frequency spectrum, the multiplication factor w from the multiplication factor generator 31 also changes in units of frequency components of a frequency spectrum.

In the multiplier 33, therefore, the level of the frequency spectra from the FFT unit 11 is controlled by the multiplication factor w. In the multiplier 34, the level of the frequency spectra from the FFT unit 12 is controlled by the multiplication factor w.

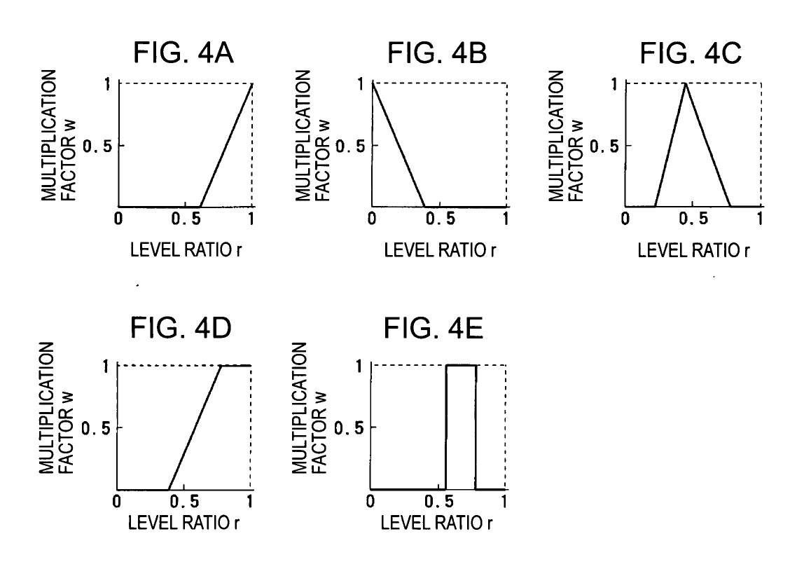

FIGS. 4A to 4E show example functions used in the function generating circuit serving as the multiplication factor generator 31. For example, when the audio signal S3 of the sound source localized at the center between the right- and left-channel sound images is to be separated from the left- and right-channel audio signals SL and SR defined in Eqs. (1) and (2), the multiplication factor generator 31 may be a function generating circuit having a characteristic shown in FIG. 4A.

In the characteristic of the function shown in FIG. 4A, the multiplication factor w is 1 or about 1 with respect to a frequency spectral component whose level ratio r between the right and left channels is 1 or close to 1, that is, a frequency spectral component having the same level or substantially the same level between the right and left channels. In a region in which the level ratio r between the right and left channels is about 0.6 or lower, the multiplication factor w is 0.

Since the multiplication factor w is 1 or close to 1 with respect to a frequency spectral component whose level ratio r supplied from the selector 25 is 1 or about 1, this frequency spectral component is output from the multipliers 33 and 34 at substantially the same level. On the other hand, the multiplication factor w is 0 with respect to a frequency spectral component whose level ratio r supplied from the selector 25 is about 0.6 or lower, and therefore, the output level of this frequency spectral component is 0. That is, this frequency spectral component is not output from the multipliers 33 and 34.

Thus, in multiple frequency spectral components, a frequency spectral component having the same level or about the same level between the right and left channels is output from the multipliers 33 and 34 at substantially the same level, and a frequency spectral component having a large level difference between the right and left channels has an output level of 0 and is not output from the multipliers 33 and 34. Therefore, only a frequency spectral component of the audio signal S3 of the sound source that is distributed in the right- and left-channel audio signals SR and SL at the same level is obtained from the adder 35.

For example, when the audio signal S1 or S5 of the sound source localized in either the right or left channel is to be separated from the left- and right-channel audio signals SL and SR defined in Eqs. (1) and (2), the multiplication factor generator 31 may be a function generating circuit having a characteristic shown in FIG. 4B.

According to the first embodiment, in order to separate the audio signal S1, the user sets a left-to-right distribution ratio of PL:PR=1:0 for the sound source to be separated. Alternatively, the user may set PL=1 and PR=0. In response to the user setting, the selection control signal SEL for controlling selection of the level ratio from the level ratio calculator 23 is supplied to the selector 25.

In order to separate the audio signal S5, the user sets a left-to-right distribution ratio of PL:PR=0:1 for the sound source to be separated. Alternatively, the user may set PL=0 and PR=1. In response to the user setting, the selection control signal SEL for controlling selection of the level ratio from the level ratio calculator 24 is supplied to the selector 25.

In the characteristic of the function shown in FIG. 4B, the multiplication factor w is 1 or about 1 with respect to a frequency spectral component whose level ratio r between the right and left channels is 0 or close to 0. In a region in which the level ratio r between the right and left channels is about 0.4 or higher, the multiplication factor w is 0.

Since the multiplication factor w is 0 or close to 0 with respect to a frequency spectral component whose level ratio r supplied from the selector 25 is 1 or about 1, this frequency spectral component is output from the multipliers 33 and 34 at substantially the same level. On the other hand, the multiplication factor w is 0 with respect to a frequency spectral component whose level ratio r supplied from the selector 25 is about 0.4 or higher, and therefore, the output level of this frequency spectral component is 0. That is, this frequency spectral component is not output from the multipliers 33 and 34.

Thus, in multiple frequency spectral components, a frequency spectral component of which one of the right and left channels has a greatly larger level than the other is output from the multipliers 33 and 34 at substantially the same level, and a frequency spectral component having a small level difference between the right and left channels has an output level of 0 and is not output from the multipliers 33 and 34. Therefore, only a frequency spectral component of the audio signal S1 or S5 of the sound source that is distributed in either the left- or right-channel audio signal SL or SR is obtained from the adder 35.

For example, when the audio signal S2 or S4 of the sound source localized in the left and right channels with a predetermined level difference is to be separated from the left- and right-channel audio signals SL and SR defined in Eqs. (1) and (2), the multiplication factor generator 31 may be a function generating circuit having a characteristic shown in FIG. 4C.

The audio signal S2 is distributed to the right and left channels by a level ratio of D2/D1 (=SR/SL)=0.4/0.9=0.44. The audio signal S4 is distributed to the right and left channels by a level ratio of D1/D2 (=SL/SR)=0.4/0.9=0.44.

According to the first embodiment, in order to separate the audio signal S2, the user sets a left-to-right distribution ratio of PL:PR=0.9:0.4 for the sound source to be separated. Alternatively, the user may set PL=0.9 and PR=0.4. Since PR/PL <1 is satisfied, the selection control signal SEL for controlling selection of the level ratio from the level ratio calculator 23 is supplied to the selector 25.

In order to separate the audio signal S4, the user sets a left-to-right distribution ratio of PL:PR=0.4:0.9 for the sound source to be separated. Alternatively, the user may set PL=0.4 and PR=0.9. Since PR/PL >1 is satisfied, the selection control signal SEL for controlling selection of the level ratio from the level ratio calculator 24 is supplied to the selector 25.

In the characteristic of the function shown in FIG. 4C, the multiplication factor w is 1 with respect to a frequency spectral component whose level ratio r between the right and left channels is equal to D2/D1 (=PR/PL)=0.4/0.9=0.44, or the multiplication factor w is 1 or about 1 with respect to a frequency spectral component having a level ratio r close to 0.44. In a region in which the level ratio r between the right and left channels is other than about 0.44, the multiplication factor w is 0.

Since the multiplication factor w is 1 or close to 1 with respect to a frequency spectral component whose level ratio r supplied from the selector 25 is 0.44 or about 0.44, this frequency spectral component is output from the multipliers 33 and 34 at substantially the same level. On the other hand, the multiplication factor w is 0 with respect to a frequency spectral component whose level ratio r supplied from the selector 25 is lower or higher than about 0.44, and therefore, the output level of this frequency spectral component is 0. That is, this frequency spectral component is not output from the multipliers 33 and 34.

Thus, in multiple frequency spectral components, a frequency spectral component whose level ratio between the right and left channels is 0.44 or about 0.44 is output from the multipliers 33 and 34 at substantially the same level, and a frequency spectral component whose level ratio r between the right and left channels is lower or higher than about 0.44 has an output level of 0 and is not output from the multipliers 33 and 34.

Therefore, only a frequency spectral component of the audio signal S2 or S4 of the sound source that is distributed in the right and left-channel audio signals SR and SL by a level ratio of 0.44 is obtained from the adder 35.

According to the first embodiment, therefore, an audio signal of a sound source that is distributed to the right and left channels by a predetermined distribution ratio can be separated from the audio signals of these two channels according to the distribution ratio.

In the first embodiment, an audio signal of a desired sound source to be separated is extracted from audio signals of both channels. However, the audio signal of the desired sound source to be separated is not necessarily separated and extracted from both channels, and may be separated and extracted from either channel.

In the first embodiment, a level ratio by which a signal of a sound source is distributed in two audio signals is used to separate the signal of the sound source from the two audio signals. However, the signal of the sound source may be separated and extracted from at least one of the two audio signals based on the level difference between the signal of the sound source and the two audio signals.

While the foregoing description has been described in the context of left- and right-channel stereo signals in which sound sources are distributed to the left and right channels according to the ratio defined in Eqs. (1) and (2), a desired sound source can also be separated from a general intentionally-undistributed stereo music signal by selecting the characteristics of the functions shown in FIGS. 4A to 4C.

With the use of other functions shown in FIGS. 4D and 4E, the range of the level ratio for separation can be changed or widened or narrowed, thereby providing different sound source selectivity.

In view of the sound source spectral characteristics, most stereo audio signals are produced from sound sources having different spectra. These sound sources can also be separated in the manner described above.

Furthermore, high-quality separation of sound sources having many overlapping spectral components can be achieved by increasing the frequency resolution in the FFT units 11 and 12, for example, by using FFT circuits having 4000 or more points.

### Second Embodiment

In the first embodiment, an audio signal of a single sound source that is distributed by a predetermined level ratio or level difference in two audio signals, specifically, the right- and left-channel stereo signals SL and SR, is separated and extracted from at least one of the two audio signals.

An audio signal processing apparatus according to a second embodiment of the present invention is adapted to separate and extract audio signals of a plurality of sound sources that are distributed in two audio signals by predetermined level ratios or level differences, rather than an audio signal of a single sound source, at a time from the two audio signals.

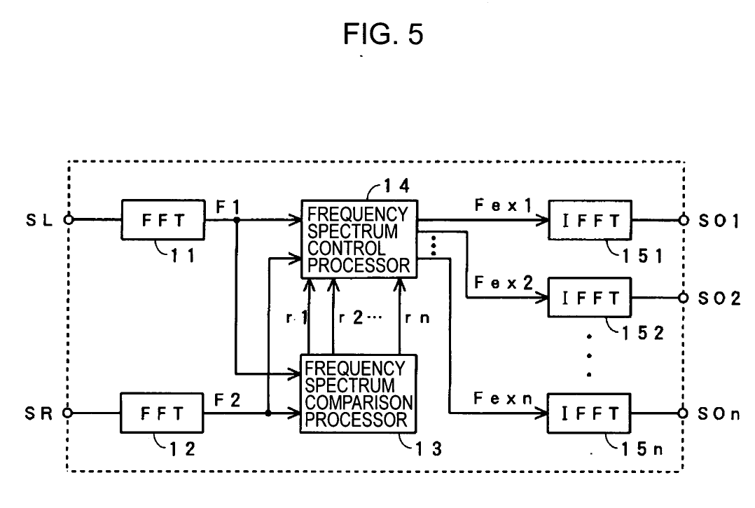

FIG. 5 shows the structure of the audio signal processing apparatus according to the second embodiment. In FIG. 5, components corresponding to those shown in FIG. 1 according to the first embodiment are assigned the same reference numerals. A frequency spectrum comparison processor 13 and a frequency spectrum control processor 14 shown in FIG. 5 are adapted to separate audio signals of a plurality of sound sources and are different from those according to the first embodiment shown in FIG. 1. Furthermore, inverse FFT units 151, 152, . . . , 15n are provided for the number of outputs to be separated and extracted.

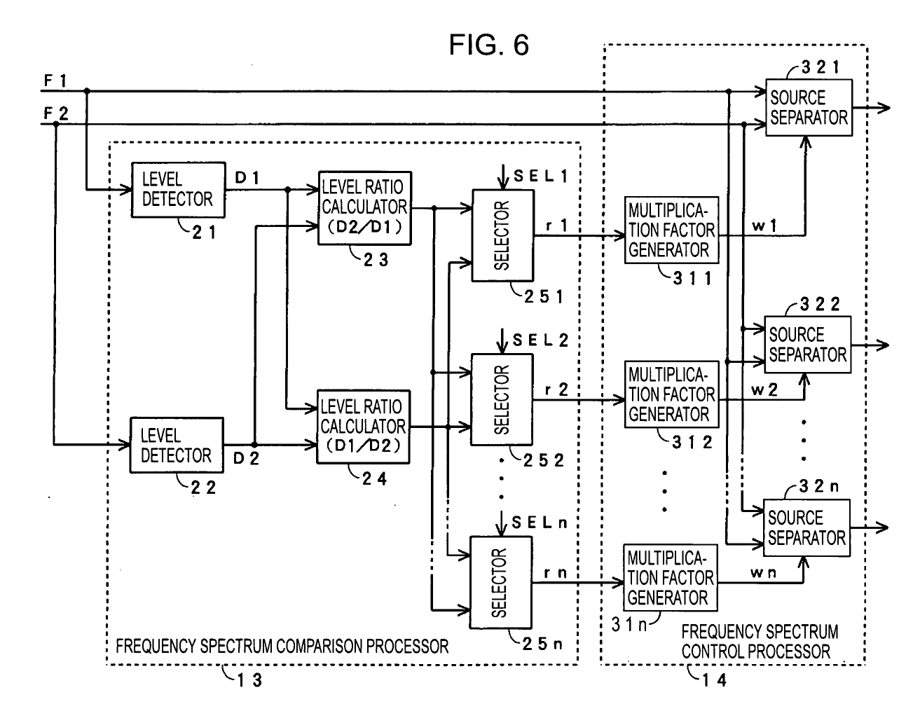

FIG. 6 shows the internal structure of the frequency spectrum comparison processor 13 and the frequency spectrum control processor 14 according to the second embodiment.

As in the first embodiment, the frequency spectrum comparison processor 13 according to the second embodiment also includes level detectors 21 and 22 and level ratio calculators 23 and 24, and detects level ratios D2/D1 and D1/D2 of frequency spectral components from the FFT units 11 and 12. The detected level ratios output from the level ratio calculators 23 and 24 are supplied to a plurality of selectors 251, 252, . . . , 25n. The number of selectors 251, 252, . . . , 25n corresponds to the number of sound sources to be separated.

The plurality of selectors 251, 252, . . . , 25n receive selection control signals SEL1, SEL2, . . . , SELn each for selecting one of the detected level ratios output from the level ratio calculators 23 and 24 depending on the distribution ratio by which an audio signal of a desired sound source to be separated is distributed to the right and left channels. As described above, each of the selection control signals SEL1, SEL2, . . . , SELn is a signal for controlling each of the selectors 251, 252, . . . , 25n to select a level ratio whose denominator is the level of the channel to which an audio signal of a desired sound source to be separated is distributed by a higher ratio.

The frequency spectrum control processor 14 includes a plurality of multiplication factor generators 311, 312, . . . , 31n and source separators 321, 322, . . . , 32n. The number of multiplication factor generators 311, 312, . . . , 31n and the number of source separators 321, 322, . . . , 32n correspond to the number of sound sources to be separated. Level ratios r1, r2, . . . , rn are supplied from the plurality of selectors 251, 252, . . . , 25n in the frequency spectrum comparison processor 13 to the multiplication factor generators 311, 312, . . . , 31n, respectively.

As in the first embodiment, each of the multiplication factor generators 311, 312, . . . , 31n sets a function (see the functions shown in FIG. 4) of the multiplication factor with respect to the level ratio corresponding to the distribution ratio by which an audio signal of a desired sound source to be separated is distributed in the right- and left-channel audio signals.

Thus, multiplication factors w1, w2, . . . , wn corresponding to the level ratios r1, r2, . . . , rn from the selectors 251, 252, . . . , 25n and also corresponding to the audio signals of the sound sources to be separated are supplied from the multiplication factor generators 311, 312, . . . , 31n to the source separators 321, 322, . . . , 32n.

Although not shown FIG. 6, as in the source separator 32 shown in FIG. 3, each of the source separators 321, 322, . . . , 32n includes a multiplier 33 for multiplying the output F1 by the multiplication factor, a multiplier 34 for multiplying the output F2 by the multiplication factor, and an adder 35 for adding the outputs of the multipliers 33 and 34.

A frequency spectral component having a level ratio equal to or close to the distribution ratio by which an audio signal of a desired sound source to be separated is distributed in the right- and left-channel audio signals is output from the multipliers 33 and 34 in each of the source separators 321, 322, . . . , 32n at substantially the same level. The other frequency spectral components have a low level or a level of 0. Therefore, extraction outputs Fex1, Fex2, . . . , Fexn of the frequency spectral components of the desired sound sources to be separated are obtained from the source separators 321, 322, . . . , 32n, respectively.

The extraction outputs Fex1, Fex2, . . . , Fexn from the source separators 321, 322, . . . , 32n are supplied to the inverse FFT units 151, 152, . . . , 15n, respectively, and are transformed back to the original time-series audio signals. The resulting signals are output as audio signal outputs SO1, SO2, . . . , SOn of the separated sound sources.

### Third Embodiment

An audio signal processing apparatus according to a third embodiment of the present invention is adapted to separate and extract an audio signal of an identical sound source or audio signals of different sound sources from a left-channel audio signal SL and a right-channel audio signal SR of right- and left-channel audio signals.

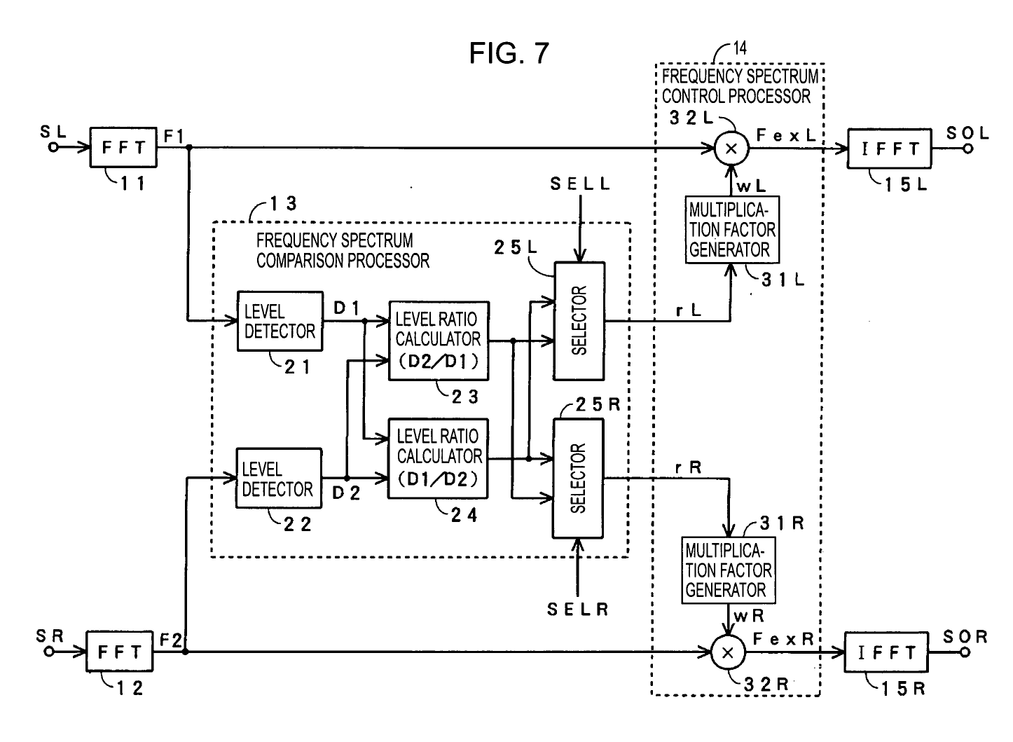

FIG. 7 is a block diagram showing the structure of the audio signal processing apparatus according to the third embodiment. In the audio signal processing apparatus shown in FIG. 7, frequency spectral components F1 and F2 output from FFT units 11 and 12 are supplied to a frequency spectrum comparison processor 13 and a frequency spectrum control processor 14.

The frequency spectrum control processor 14 outputs a frequency spectral component output FexL of an audio signal of a predetermined sound source which is extracted from the left-channel audio signal SL and a frequency spectral component output FexR of an audio signal of a predetermined sound source which is extracted from the right-channel audio signal SR, as described below. The frequency spectral component outputs FexL and FexR are supplied to inverse FFT units 15L and 15R, respectively, and are transformed back to the original time-series audio signals. The resulting signals are derived from the inverse FFT units 15L and 15R as output audio signals SOL and SOR of the predetermined sound sources.

As in the first embodiment, the frequency spectrum comparison processor 13 according to the third embodiment also includes level detectors 21 and 22, and level ratio calculators 23 and 24, and detects level ratios D2/D1 and D1/D2 of frequency spectral components from the FFT units 11 and 12. The detected level ratios output from the level ratio calculators 23 and 24 are supplied to a left-channel selector 25L and a right-channel selector 25R.

The selectors 25L and 25R receive selection control signals SELL and SELR each for selecting one of the detected level ratios output from the level ratio calculators 23 and 24 depending on the distribution ratio by which an audio signal of a desired sound source to be separated from each of the right and left channels is distributed to the right and left channels. As described above, each of the selection control signals SELL and SELR is a signal for controlling each of the selectors 25L and 25R to select a level ratio whose denominator is the level of the channel to which an audio signal of a desired sound source to be separated is distributed by a higher ratio.

The frequency spectrum control processor 14 includes a left-channel multiplication factor generator 31L, a right-channel multiplication factor generator 31R, a left-channel multiplier 32L, and a right-channel multiplier 32R. A level ratio rL is supplied to the multiplication factor generator 31L from the selector 25L in the frequency spectrum comparison processor 13, and a level ratio rR is supplied to the multiplication factor generator 31R from the selector 25R.

As in the first embodiment, each of the multiplication factor generators 31L and 31R sets a function (see the functions shown in FIG. 4) of the multiplication factor with respect to the level ratio corresponding to the distribution ratio by which an audio signal of a desired sound source to be separated is distributed in the right- and left-channel audio signals.

Thus, multiplication factors wL and wR corresponding to the level ratios rL and rR from the selectors 25L and 25R and also corresponding to the audio signals of the desired sound sources to be separated are supplied from the multiplication factor generators 31L and 31R to the multipliers 32L and 32R, respectively.

A frequency spectral component having a level ratio equal to or close to the distribution ratio by which an audio signal of a desired sound source to be separated is distributed in the right- and left-channel audio signals is output from each of the multipliers 32L and 32R at substantially the same level. The other frequency spectral components have a low level or a level of 0. Therefore, extraction outputs FexL and FexR of the frequency spectral components of the desired sound sources to be separated are obtained from the multipliers 32L and 32R, respectively.

The extraction outputs FexL and FexR from the multipliers 32L and 32R are supplied to the inverse FFT units 15L and 15R, respectively, and are transformed back to the original time-series audio signals. The resulting signals are output as the audio signal outputs SOL and SOR of the separated sound sources.

In the third embodiment, the functions set in the multiplication factor generators 31L and 31R may be functions suitable for separating not only audio signals of different sound sources to be separated from the right and left channels but also audio signals of an identical sound source distributed by a predetermined level ratio or level difference to the right and left channels.

In the latter case, the selectors 25L and 25R may selectively output the same level ratio from the level ratio calculators 23 and 24, and the multiplication factor generators 31L and 31R may use the same function. Therefore, for example, the signal S2 or S4 in the left- and right-channel stereo signals SL and SR defined in Eqs. (1) and (2) can be separated and extracted from the left- and right-channel audio signals SL and SR, and can be derived as the outputs SOL and SOR.

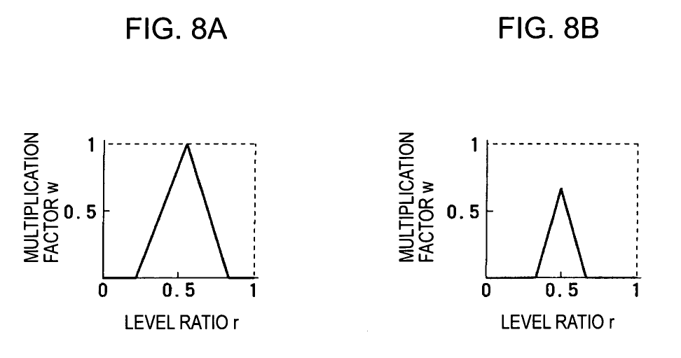

When an identical sound source is to be separated, functions of the level ratio versus the multiplication factor, which are set in the multiplication factor generators 31L and 31R, may not have the same characteristic. For example, as shown in FIGS. 8A and 8B, the functions may exhibit homothetic characteristic curves having different multiplication factor w with respect to the level ratio r.

Therefore, for example, an audio signal of a sound source distributed to the right and left channels with a level difference can be output at the same level as the audio signals SOL and SOR separated from the left- and right-channel audio signals SL and SR.

### Fourth Embodiment

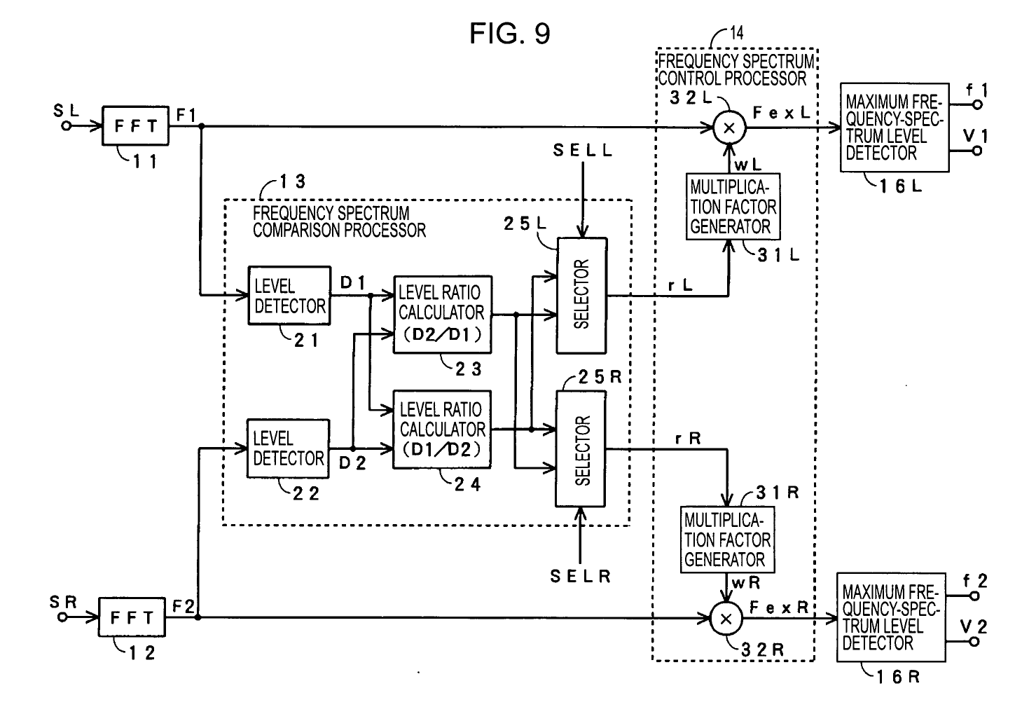

FIG. 9 shows an automatic music transcription apparatus according to a fourth embodiment of the present invention as a modification of the audio signal processing apparatus according to the third embodiment shown in FIG. 8.

The automatic music transcription apparatus according to the fourth embodiment shown in FIG. 9 includes maximum frequency-spectrum level detectors 16L and 16R, in place of the inverse FFT units 15L and 15R shown in FIG. 7, at the output side of the frequency spectrum control processor 14.

According to the fourth embodiment, due to the spectral structure of a separated sound source, a frequency spectral component having the maximum amplitude level is the fundamental tone of this sound source. Thus, the maximum frequency-spectrum level detectors 16L and 16R detect frequencies of frequency spectral components having the maximum amplitude level from the outputs FexL and FexR from the frequency spectrum control processor 14, and output the detected frequencies f1 and f2 and the levels V1 and V2 as data.

Although not shown in FIG. 9, the frequencies f1 and f2 and the levels V1 and V2 from the maximum frequency-spectrum level detectors 16L and 16R may be supplied to, for example, a pitch detector to detect the pitch of sounds, and the detected pitch may be recorded onto a recording medium or may be written down on a musical score using a score writing apparatus (or a music transcription apparatus).

According to the fourth embodiment, therefore, a sound source is first separated from stereo audio signals, and the spectrum of the separated sound source is then analyzed to detect the pitch of sounds from the sound source. Based on the detected pitch, automatic music transcription is performed. Therefore, a system capable of automatic music transcription from stereo sound sources having a combination of a plurality of sound sources can be realized.

While the apparatus shown in FIG. 9 separates a sound source from each of the right and left channels and performs automatic music transcription, an apparatus according to the second embodiment shown in FIGS. 5 and 6 that extracts frequency spectral components of a plurality of sound sources from each of the two-channel audio signals may also be implemented as an automatic music transcription apparatus. In this case, all inverse FFT units 151, 152, . . . , 15n shown in FIG. 5 are replaced by maximum frequency-spectrum level detectors to obtain the frequencies and levels of frequency spectra having the maximum-level, and the output frequencies and levels are supplied to a music transcription apparatus via a pitch detector.

The automatic music transcription apparatus according to the fourth embodiment can also be applied to the audio signal processing apparatus according to the first embodiment. It is to be understood that the automatic music transcription apparatus according to the fourth embodiment can also be applied to an audio signal processing apparatus for sound source separation according to the following embodiments.

### Fifth Embodiment

An audio signal processing apparatus according to a fifth embodiment of the present invention is adapted to allow a user to dynamically change a sound source to be separated from two-channel audio signals.

Specifically, the audio signal processing apparatus according to the fifth embodiment is applied to the audio signal processing apparatus according to the third embodiment, and is adapted to allow a user to dynamically select and change a sound source or sound sources to be separated when audio signals of different sound sources (or an audio signal of an identical sound source) are to be separated from each of the two-channel audio signals SL and SR.

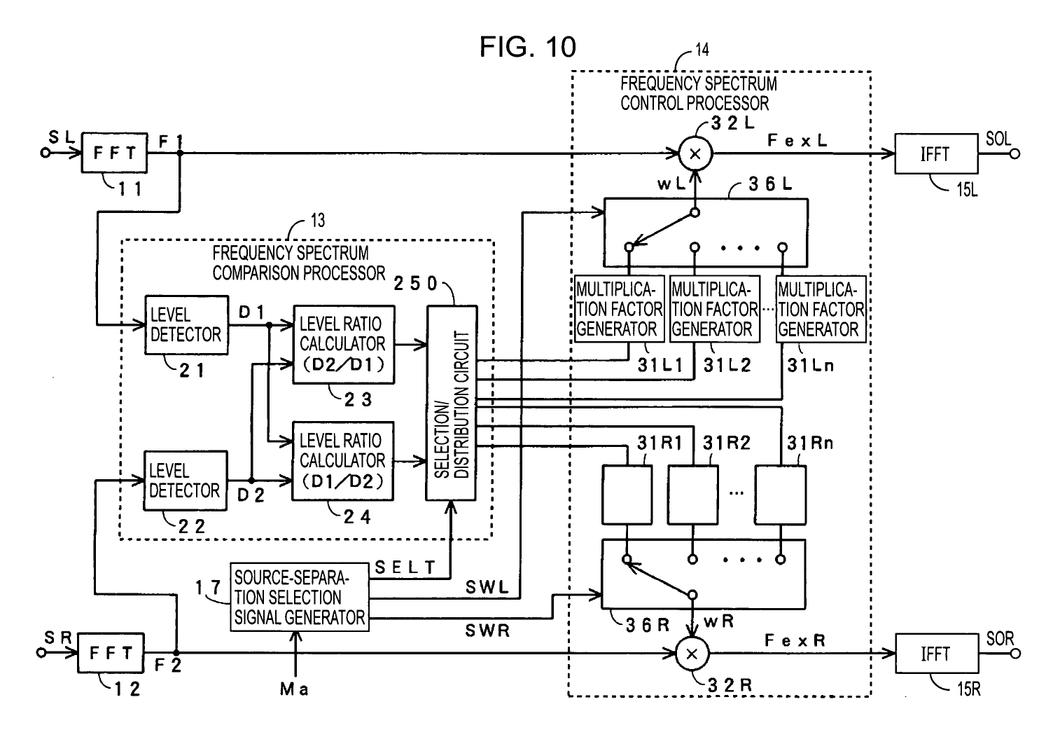

Referring to FIG. 10, according to the fifth embodiment, a frequency spectrum control processor 14 includes a plurality of left-channel multiplication factor generators 31L1, 31L2, . . . , 31Ln, and a switch circuit 36L. The switch circuit 36L selects a multiplication factor generated from any one of the plurality of multiplication factor generators 31L1, 31L2, . . . , 31Ln, and supplies the selected multiplication factor to a multiplier 32L as a multiplication factor wL.

The frequency spectrum control processor 14 further includes a plurality of right-channel multiplication factor generators 31R1, 31R2, . . . , 31Rn, and a switch circuit 36R. The switch circuit 36R selects a multiplication factor generated from any one of the plurality of multiplication factor generators 31R1, 31R2, . . . , 31Rn, and supplies the selected multiplication factor to a multiplier 32R as a multiplication factor wR.

For example, each of the plurality of multiplication factor generators 31L1, 31L2, . . . , 31Ln, 31R1, 31R2, . . . , 31Rn sets a function of the level ratio versus the multiplication factor that is used to separate a sound source whose level ratio has various values between the right and left channels.

A frequency spectrum comparison processor 13 includes a selection and distribution circuit 250. The selection and distribution circuit 250 receives level ratio outputs from level ratio calculators 23 and 24, and supplies either level ratio output to each of the multiplication factor generators 31L1, 31L2, . . . , 31Ln, 31R1, 31R2, . . . , 31Rn.

The audio signal processing apparatus according to the fifth embodiment further includes a source-separation selection signal generator 17. The source-separation selection signal generator 17 generates a selection signal SELT to be supplied to the selection and distribution circuit 250 in response to a signal Ma that is operated by the user using a selection operating unit, described below, to select a sound source to be separated. The source-separation selection signal generator 17 further generates a signal SWL for controlling the switching operation of the switch circuit 36L and a signal SWR for controlling the switching operation of the switch circuit 36R.

Although not shown in FIG. 10, the audio signal processing apparatus according to the fifth embodiment receives a sound source selection operation from the user using, for example, a selection operating lever or button or a graphical user interface on a display unit such as a liquid crystal display (LCD) with a touch panel. The sound sources to be selected by the user operation are a plurality of sound sources that can be separated by the functions set in the multiplication factor generators 31L1, 31L2, . . . , 31Ln, 31R1, 31R2, . . . , 31Rn.

For example, the plurality of sound sources that can be separated may be sound sources whose sound image localization positions slightly change between the sound image localization position in the left channel and the sound image localization position in the right channel.

The user can independently specify desired sound sources in each of the right and left channels.

For example, when a sound source that can be separated from the left-channel audio signal SL using the multiplication factor from the left-channel multiplication factor generator 31L1 is selected by the user using the selection operating lever or button or the graphical user interface, the source-separation selection signal generator 17 receives the signal Ma corresponding to the selection operation, and generates the switch control signal SWL and the selection signal SELT according to the signal Ma.

The switch circuit 36L is switched to select the multiplication factor generator 31L1 by the switch control signal SWL from the source-separation selection signal generator 17. The selection and distribution circuit 250 is controlled by the selection signal SELT to select the level ratio calculator 23 or 24 (which outputs a level ratio of 1 or lower), and the selected level ratio is supplied to the multiplication factor generator 31L1.

Thus, the frequency spectral component FexL of the selected sound source is obtained from the multiplier 32L, and is transformed back to the original time-series audio signal by the inverse FFT unit 15L, which is then output as an output SOL.

Also in the right channel, an audio signal of a desired sound source to be separated, which is selected by the user, is extracted.

According to the fifth embodiment shown in FIG. 10, an audio signal of a predetermined sound source is separated and extracted from each of two-channel audio signals (that is, the audio signal processing apparatus according to the fifth embodiment is applied to the third embodiment). The audio signal processing apparatus according to the fifth embodiment may be applied to the first or second embodiment.

For example, when the audio signal processing apparatus according to the fifth embodiment is applied to the first embodiment, a plurality of multiplication factor generators are provided in place of the multiplication factor generator 31 shown in FIG. 3, and a switch circuit is provided between the plurality of multiplication factor generators and the sound source separator 32 to supply a multiplication factor from one of the plurality of multiplication factor generators to the sound source separator 32. A source-separation selection signal generator is further provided to control the switching operation of the switch circuit in response to the selection operation signal Ma from the user and to generate a control signal for performing a control to supply an appropriate level from one of the level ratio calculators 23 and 24 to the multiplication factor generators.

For example, when the audio signal processing apparatus according to the fifth embodiment is applied to the second embodiment, a plurality of multiplication factor generators are provided in place of each of the multiplication factor generators 311, 312, . . . , 31n shown in FIG. 6, and a plurality of switch circuits are provided between the plurality of multiplication factor generators and each of the sound source separators 321, 322, . . . , 32n to supply a multiplication factor from one of the plurality of multiplication factor generators to each of the sound source separators 321, 322, . . . , 32n. A source-separation selection signal generator is further provided to generate a switch control signal for controlling the switching operation of each of the switch circuits in response to a selection operation signal Ma from the user and to generate a control signal for performing a control to supply an appropriate level output from one of the level ratio calculators 23 and 24 to each of the multiplication factor generators.

### Sixth Embodiment

In the foregoing embodiments, an audio signal of a sound source is distributed in-phase in two-channel audio signals. An audio signal of a sound source may be distributed in opposite phase. Audio signals S1 to S6 from six sound sources MS1 to MS6 are distributed to the left and right channels to produce stereo audio signals SL and SR defined in Eqs. (3) and (4) as below, by way of example:
SL=S1+0.9S2+0.7S3+0.4S4+0.7S6 Eq. (3)
SR=S5+0.4S2+0.7S3+0.9S4−0.7S6 Eq. (4)

The audio signal S3 of the sound source MS3 and the audio signal S6 of the sound source MS6 are distributed to the right and left channels at the same level. However, the audio signal S3 of the sound source MS3 is distributed in phase to the right and left channels, and the audio signal S6 of the sound source MS6 is distributed in opposite phase to the right and left channels.

If the audio signal S3 of the sound source MS3 or the audio signal S6 of the sound source MS6 is to be separated and extracted in the manner described in the foregoing embodiments based on only the level ratio or level difference without consideration of the phases, it is difficult to separate and extract either signal because the audio signals S3 and S6 are distributed to the right and left channels at the same level.

According to the sixth embodiment, the audio signal S3 of the sound source MS3 and the audio signal S6 of the sound source MS6 are separated and output by separating audio components using, first, the level ratio or level difference in a similar manner to that in the foregoing embodiments and, then, the phase difference.

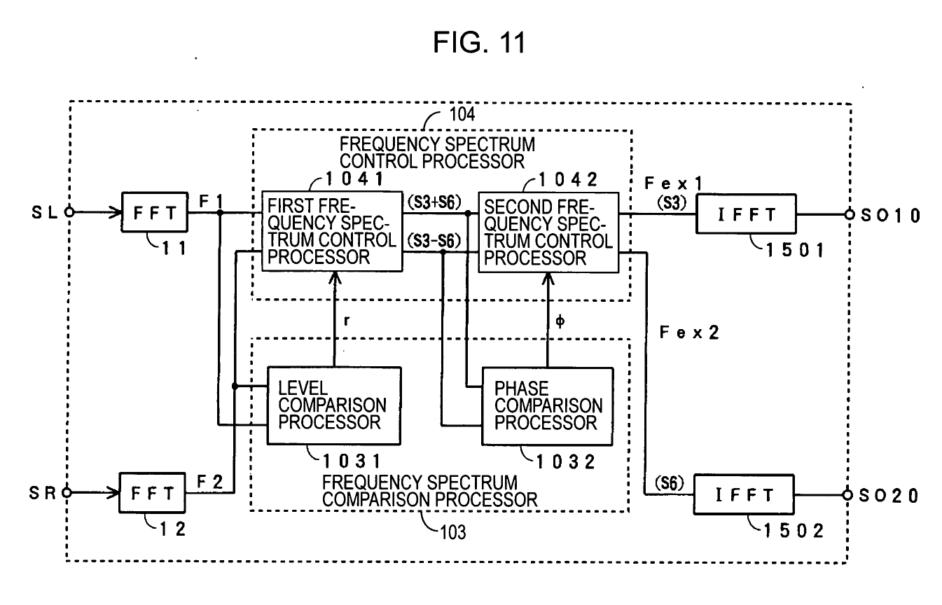

FIG. 11 is a block diagram showing the structure of an audio signal processing apparatus according to the sixth embodiment. The audio signal processing apparatus according to the sixth embodiment includes a frequency spectrum comparison processor 103, and the frequency spectrum comparison processor 103 includes a level comparison processor 1031 and a phase comparison processor 1032.

The audio signal processing apparatus according to the sixth embodiment further includes a frequency spectrum control processor 104, and the frequency spectrum control processor 104 includes a first frequency spectrum control processor 1041 and a second frequency spectrum control processor 1042 for sound source separation based on the phase difference.

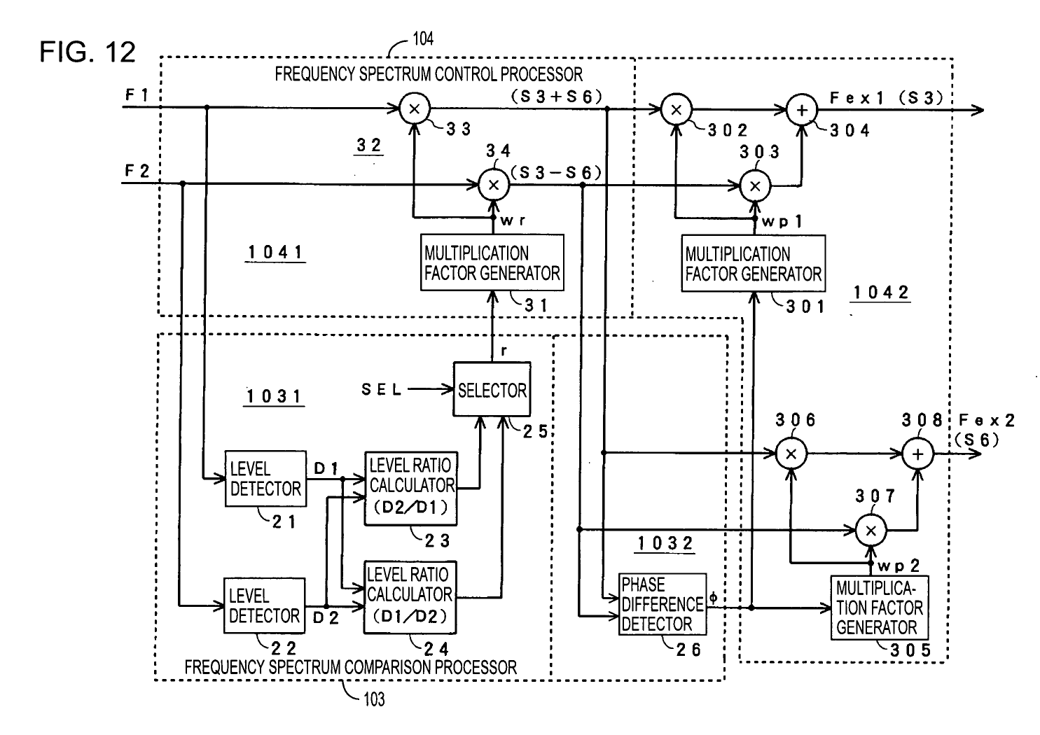

FIG. 12 is a block diagram showing the details of the structure of the frequency spectrum comparison processor 103 and the frequency spectrum control processor 104 according to the sixth embodiment. The level comparison processor 1031 in the frequency spectrum comparison processor 103 has a similar structure to that of the frequency spectrum comparison processor 13 according to the first embodiment, and includes level detectors 21 and 22, level ratio calculators 23 and 24, and a selector 25.

The first frequency spectrum control processor 1041 in the frequency spectrum control processor 104 has a similar structure to that of the frequency spectrum control processor 14 according to the first embodiment, except that the frequency spectrum control processor 1041 does not include the adder 35. The first frequency spectrum control processor 1041 includes a multiplication factor generator 31, and a sound source separator 32 including multipliers 33 and 34.

As shown in FIGS. 11 and 12, a level ratio output r from the level comparison processor 1031 is supplied to the multiplication factor generator 31 in the first frequency spectrum control processor 1041 in the manner described in the first embodiment, and the multiplication factor generator 31 generates a multiplication factor wr according to the function set in the multiplication factor generator 31. The multiplication factor wr is supplied to the multipliers 33 and 34.

A frequency spectral component F1 from the FFT unit 11 is supplied to the multiplier 33, and the result of multiplication of the frequency spectral component F1 and the multiplication factor wr is supplied from the multiplier 33. A frequency spectral component F2 from the FFT unit 12 is supplied to the multiplier 34, and the result of the frequency spectral component F2 and the multiplication factor wr is supplied from the multiplier 34.

That is, the frequency spectral components F1 and F2 from the FFT units 11 and 12, which are level-controlled according to the multiplication factor wr from the multiplication factor generator 31, are output from the multipliers 33 and 34.

As described above, the multiplication factor generator 31 may be a function generating circuit for generating a function with respect to the multiplication factor wr, wherein the level ratio r is a variable. The function used in the multiplication factor generator 31 depends on the distribution ratios by which a sound source to be separated is distributed in right- and left-channel audio signals.

For example, the multiplication factor generator 31 sets a function of the multiplication factor wr with respect to the level ratio shown in FIGS. 4A to 4E. For example, when an audio signal of a sound sources distributed to the right and left channels at the same level is separated and extracted, as described above, the multiplication factor generator 31 sets the specific function shown in FIG. 4A.

According to the sixth embodiment, the outputs of the multipliers 33 and 34 are supplied to the phase comparison processor 1032 in the frequency spectrum comparison processor 103 and the second frequency spectrum control processor 1042 in the frequency spectrum control processor 104.

As shown in FIG. 12, the phase comparison processor 1032 includes a phase difference detector 26 for detecting a phase difference φ between the outputs of the multipliers 33 and 34. The phase difference detector 26 supplies information about the phase difference φ to the second frequency spectrum control processor 1042.

The second frequency spectrum control processor 1042 includes multiplication factor generators 301 and 305, multipliers 302, 303, 306, and 307, and adders 304 and 308.

The output of the multiplier 33 in the first frequency spectrum control processor 1041 and a multiplication factor wp1 from the multiplication factor generator 301 are supplied to the multiplier 302. The multiplier 302 multiples the output of the multiplier 33 by the multiplication factor wp1, and supplies the result of multiplication to the adder 304. The output of the multiplier 34 in the first frequency spectrum control processor 1041 and the multiplication factor wp1 from the multiplication factor generator 301 are supplied to the multiplier 303. The multiplier 303 multiples the output of the multiplier 34 by the multiplication factor wp1, and supplies the result of multiplication to the adder 304. The adder 304 outputs a first output Fex1 of the frequency spectrum control processor 104.

The output of the multiplier 33 in the first frequency spectrum control processor 1041 and a multiplication factor wp2 from the multiplication factor generator 305 are supplied to the multiplier 306. The multiplier 306 multiples the output of the multiplier 33 by the multiplication factor wp2, and supplies the result of multiplication to the adder 308. The output of the multiplier 34 in the first frequency spectrum control processor 1041 and the multiplication factor wp2 from the multiplication factor generator 305 are supplied to the multiplier 307. The multiplier 307 multiples the output of the multiplier 34 by the multiplication factor wp2, and supplies the result of multiplication to the adder 308. The adder 308 outputs a second output Fex2 of the frequency spectrum control processor 104.

The multiplication factor generators 301 and 305 receive the information about the phase difference φ from the phase difference detector 26, and generate the multiplication factors wp1 and wp2 based on the phase difference φ. The multiplication factor generators 301 and 305 may be function generating circuits for generating functions with respect to the multiplication factor wp, wherein the phase difference φ is a variable. The functions used in the multiplication factor generators 301 and 305 are determined by the user depending on the phase differences between a sound source to be separated and the two channels.

The phase difference φ supplied to the multiplication factor generators 301 and 305 changes in units of frequency components of a frequency spectrum. Thus, the multiplication factors wp1 and wp2 from the multiplication factor generators 301 and 305 also change in units of frequency components of a frequency spectrum.

In the multipliers 302 and 306, therefore, the level of the frequency spectra from the multiplier 33 is controlled by the multiplication factors wp1 and wp2. In the multipliers 303 and 307, the level of the frequency spectra from the multiplier 34 is controlled by the multiplication factors wp1 and wp2.

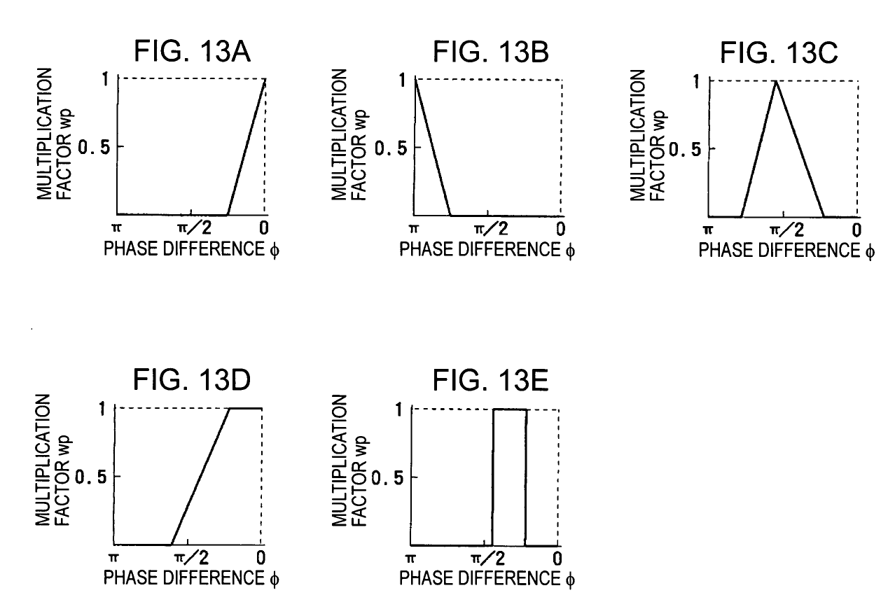

FIGS. 13A to 13E show example functions used in the function generating circuits serving as the multiplication factor generators 301 and 305.

In the characteristic of the function shown in FIG. 13A, the multiplication factor wp is 1 or about 1 with respect to a frequency spectral component whose a phase difference φ between the right and left channels is 0 or close to 0, that is, a frequency spectral component of which the right and left channels are in phase or close to in phase. In a region in which the phase difference φ between the right and left channels is about π/4 or higher, the multiplication factor wp is 0.

For example, when the multiplication factor generator 301 sets the function having the characteristic shown in FIG. 13A, the multiplication factor wp is 1 or about 1 with respect to a frequency spectral component whose phase difference φ supplied from the phase difference detector 26 is 0 or about 0. Thus, this frequency spectral component is output from the multipliers 302 and 303 at substantially the same level. On the other hand, the multiplication factor wp is 0 with respect to a frequency spectral component whose phase difference φ supplied from the phase difference detector 26 is about π/4 or higher, and therefore, the output level of this frequency spectral component is 0. That is, this frequency spectral component is not output from the multipliers 302 and 303.

Thus, in multiple frequency spectral components, a frequency spectral component of which the right and left channels are in phase or the phase difference therebetween is small is output from the multipliers 302 and 303 at substantially the same level, and a frequency spectral component having a large phase difference between the right and left channels has an output level of 0 and is not output from the multipliers 302 and 303. Therefore, only a frequency spectral component of an audio signal of a sound source that is distributed in-phase in the right- and left-channel audio signals SL and SR is obtained from the adder 304.

The function having the characteristic shown in FIG. 13A is therefore used for extracting a signal of a sound source that is distributed in-phase to the right and left channels.

In the characteristic of the function shown in FIG. 13B, the multiplication factor wp is 1 or about 1 with respect to a frequency spectral component whose phase difference φ between the right and left channels is π or close to π, that is, a frequency spectral component of which the right and left channels are in opposite phase or close to in opposite phase. In a region in which the phase difference φ between the right and left channels is about 3π/4 or lower, the multiplication factor wp is 0.

For example, when the multiplication factor generator 301 sets the function having the characteristic shown in FIG. 13B, the multiplication factor wp is 1 or close to 1 with respect to a frequency spectral component whose phase difference φ supplied from the phase difference detector 26 is π or about π. Thus, this frequency spectral component is output from the multipliers 302 and 303 at substantially the same level. On the other hand, the multiplication factor wp is 0 with respect to a frequency spectral component whose phase difference φ supplied from the phase difference detector 26 is about 3π/4 or lower, and therefore, the output level of this frequency spectral component is 0. That is, this frequency spectral component is not output from the multipliers 302 and 303.

Thus, in multiple frequency spectral components, a frequency spectral component of which the right and left channels are in opposite phase or the phase difference therebetween is large is output from the multipliers 302 and 303 at substantially the same level, and a frequency spectral component having a small phase difference between the right and left channels has an output level of 0 and is not output from the multipliers 302 and 303. Therefore, only a frequency spectral component of an audio signal of a sound source that is distributed in opposite phase in the right- and left-channel audio signals SL and SR is obtained from the adder 304.

The function having the characteristic shown in FIG. 13B is therefore used for extracting a signal of a sound source that is distributed in opposite phase to the right and left channels.

In the function having a characteristic shown in FIG. 13C, the multiplication factor wp is 1 or about 1 with respect to a frequency spectral component whose phase difference φ between the right and left channels is about π/2 or close to about π/2. In a region in which the phase difference φ is other than about π/2, the multiplication factor wp is 0. The function having the characteristic shown in FIG. 13C is therefore used for extracting a signal of a sound source that is distributed about π/2 out of phase to the right and left channels.

The multiplication factor generators 301 and 305 may use a function having a characteristic shown in FIG. 13D or 13E depending on the phase difference by which an audio signal of a sound source to be separated is distributed to two channels.

The first output Fex1 and the second output Fex2 obtained from the frequency spectrum control processor 104 accordingly are supplied to inverse FFT units 1501 and 1502, respectively, and are transformed back to the original time-series audio signals. The resulting signals are derived as first and second output signals SO10 and S)20. When the first and second output signals SO10 and SO20 are to be derived as analog signals, D/A converters are provided at the output stages of the inverse FFT units 1501 and 1502.

In the sixth embodiment, for example, when the audio signal S3 of the sound source MS3 distributed in-phase to the right and left channels and the audio signal S6 of the sound source MS6 distributed in opposite phase to the right and left channels, where the audio signals S3 and S6 are distributed at the same level, are to be separated as the outputs Fex1 and Fex2 from the right- and left-channel audio signals SL and SR defined in Eqs. (3) and (4), the multiplication factor generator 31 sets the specific function shown in FIG. 4A, and the multiplication factor generators 301 and 305 sets the functions having the characteristics shown in FIGS. 13A and 13B, respectively.

In this case, as shown in FIGS. 11 and 12, in the first frequency spectrum control processor 1041 in the frequency spectrum control processor 104, the multiplier 33 outputs a frequency spectral component (S3+S6) of the FFT signal (frequency spectrum) of the left-channel audio signal SL, and the multiplier 34 outputs a frequency spectral component (S3−S6) of the FFT signal (frequency spectrum) of the right-channel audio signal SR. That is, the signals S3 and S6 are output from the first frequency spectrum control processor 1041 without being separated because the signals S3 and S6 are distributed to the right and left channels at the same level.

According to the sixth embodiment, the signals S3 and S6 that are distributed in opposite phase to the right and left channels are separated in the following manner.

The outputs of the multipliers 33 and 34 are supplied to the phase difference detector 26 in the phase comparison processor 1032 in the frequency spectrum comparison processor 103 to detect the phase difference φ between the outputs of the multipliers 33 and 34. The information about the phase difference φ detected by the phase difference detector 26 is supplied to the multiplication factor generator 301 and the multiplication factor generator 305.

The function having the characteristic shown in FIG. 13A set in the multiplication factor generator 301 allows the multipliers 302 and 303 to extract an audio signal of a sound source that is distributed in phase to the right and left channels. Thus, only the frequency spectral component of the audio signal S3 of the sound source MS3 in-phase in the frequency spectral components (S3+S6) and (S3−S6) is obtained from each of the multipliers 302 and 303, and is supplied to the adder 304.

The frequency spectral component of the audio signal S3 of the sound source MS3 is therefore derived as the output signal Fex1 from the adder 304, and is supplied to the inverse FFT unit 1501. The separated audio signal S3 is transformed back to the time-series signal by the inverse FFT unit 1501, and is then output as the output signal SO10.

The function having the characteristic shown in FIG. 13B set in the multiplication factor generator 305 allows the multipliers 306 and 307 to extract an audio signal of a sound source that is distributed in opposite phase to the right and left channels. Thus, only the frequency spectral component of the audio signal S6 of the sound source MS6 in opposite phase in the frequency spectral components (S3+S6) and (S3−S6) is obtained from each of the multipliers 306 and 307, and is supplied to the adder 308.

The frequency spectral component of the audio signal S6 of the sound source MS6 is therefore derived as the output signal Fex2 from the adder 308, and is supplied to the inverse FFT unit 1502. The separated audio signal S6 is transformed back to the time-series signal by the inverse FFT unit 1502 and is then output as the output signal SO20.

In the sixth embodiment described with reference to FIGS. 11 and 12, two signals that are not separated using the level ratio by the first frequency spectrum control processor 1041, e.g., the in-phase signal S3 and the opposite-phase signal S6, are separated by the second frequency spectrum control processor 1042 using individual multiplication factors and multipliers. Alternatively, one of two signals that are not separated using the level ratio may be separated using the phase difference φ and the multiplication factor, and the separated signal may be subtracted from the sum of the signals from the first frequency spectrum control processor 1041 (or the sum of the output from the multiplier 33 and the output from the multiplier 34) to separate the other signal of the two signals.

While two separated sound source signals are obtained in the sixth embodiment described with reference to FIGS. 11 and 12, the number of separated sound source signals to be output may be one. The audio signal processing apparatus according to the sixth embodiment can also be applied to the audio signal processing apparatus according to the second embodiment to separate audio signals of multiple sound sources at a time.

According to the sixth embodiment described with reference to FIGS. 11 and 12, sound-source components distributed at the same level in two audio signals are extracted based on a level ratio of two frequency spectra, and thereafter a desired sound source is separated based on a phase difference between two frequency spectra of the extracted sound-source components. When input audio signals are two audio signals, e.g., (S3+S6) and (S3−S6), it is to be understood that a sound source can be separated based on only the phase difference.

The audio signal processing apparatus according to the sixth embodiment can also be applied to the automatic music transcription apparatus according to the fourth embodiment.

### Seventh Embodiment

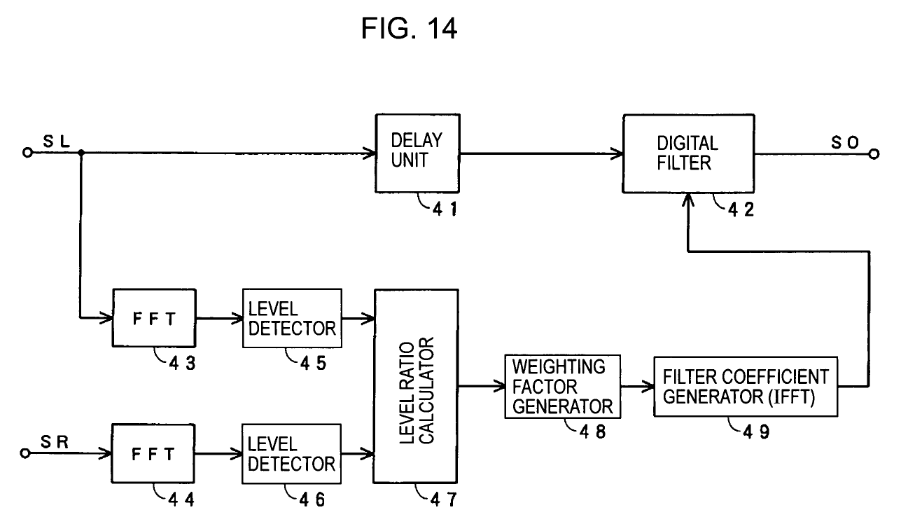

FIG. 14 is a block diagram showing the structure of an audio signal processing apparatus according to a seventh embodiment of the present invention. The audio signal processing apparatus shown in FIG. 14 is adapted to separate an audio signal of a sound source distributed by a predetermined level ratio or level difference to the right and left channels from one of left- and right-channel audio signals SL and SR, e.g., the left-channel audio signal SL in the example shown in FIG. 14, using a digital filter 42.

The left-channel audio signal (in this example, a digital signal) SL is supplied to the digital filter 42 via a timing-adjustment delay unit 41. The digital filter 42 receives a filter coefficient, described below, which is generated based on the level ratio by which an audio signal of a desired sound source to be separated is distributed to the right and left channels, and the audio signal of the desired sound source is extracted from the digital filter 42.

The filter coefficient is generated in the following manner. First, the left- and right-channel audio signals (digital signals) SL and SR are supplied to FFT units 43 and 44, respectively, and are subjected to FFT processing so that the time-series audio signal is transformed into frequency-domain data. Multiple frequency spectral components having different frequencies are output from each of the FFT units 43 and 44.

The frequency spectral components output from the FFT units 43 and 44 are supplied to level detectors 45 and 46, respectively, to detect the amplitude spectra or power spectra of the frequency spectral components, thereby detecting the levels D1 and D2. The levels D1 and D2 detected by the level detectors 45 and 46 are supplied to a level ratio calculator 47 to determine the level ratios D1/D2 or D2/D1.

The level ratios determined by the level ratio calculator 47 are supplied to a weighting factor generator 48. The weighting factor generator 48 corresponds to the multiplication factor generator according to the foregoing embodiments. The weighting factor generator 48 outputs a large weighting factor with respect to a level ratio equal to or close to the level ratio by which an audio signal of a sound source to be separated is mixed in the right- and left-channel audio signals, and outputs a small weighting factor with respect to other level ratios. The weighting factor is obtained for each of the frequencies of the frequency spectral components output from the FFT units 43 and 44.

The frequency-domain weighting factor from the weighting factor generator 48 is supplied to a filter coefficient generator 49, and is transformed into a time-domain filter coefficient. The filter coefficient generator 49 performs inverse FFT on the frequency-domain weighting factor to generate a filter coefficient to be supplied to the digital filter 42.

The filter coefficient from the filter coefficient generator 49 is supplied to the digital filter 42. The digital filter 42 separates and extracts an audio signal component of a sound source corresponding to the function set in the weighting factor generator 48, and output it as an output SO. The delay until 41 adjusts the processing delay time until the filter coefficient to be supplied to the digital filter 42 is generated.

While only the level ratio is taken into consideration in the example shown in FIG. 14, only the phase difference or a combination of the level ratio and the phase difference may be taken into consideration. For example, when a combination of the level ratio and the phase difference is taken into consideration, the outputs of the FFT units 43 and 44 are also supplied to a phase difference detector (not shown), and a phase difference detected by the phase difference detector is supplied to a weighting factor generator. This weighting factor generator is a function generating circuit for generating a weighting factor with respect to both a variable level difference and a variable phase difference by which a sound source to be separated is distributed in the right- and left-channel audio signals.

Therefore, the weighting factor generator sets a function designed to generate a large weighting factor with respect to a level ratio equal to or close to the level ratio by which an audio signal of a sound source to be separated is distributed to the right and left channels and with respect to a phase difference equal to or close to the phase difference by which the audio signal of the sound source to be separated is distributed to the right and left channels, and sets a function designed to generate a small factor, otherwise.

The weighting factor from the weighting factor generator is subjected to inverse FFT processing to generate a filter coefficient of the digital filter 42.

Although an audio signal of a desired sound source is separated only from the left channel in FIG. 14, an audio signal of a predetermined sound source can also be separated from the right-channel audio signal by separately providing a similar system for generating a filter coefficient. Other Embodiments In the foregoing embodiments, since it is difficult to perform FFT processing on an input audio signal that is a long time-series signal, such as music, the time-series signal is segmented into predetermined analysis frames so that FFT processing is performed on a data segment in each of the frames.

However, if time-series data is segmented into frames having a certain length and is subjected to sound source separation before performing inverse FFT to combine the frames, the waveform of the time-series data subjected to inverse FFT processing may be discontinuous at frame boundaries, which are heard as noise.

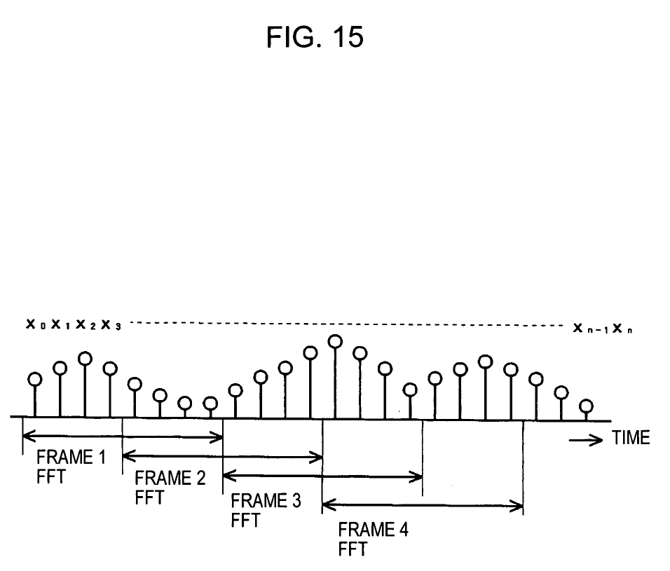

According to an eighth embodiment of the present invention, as shown in FIG. 15, data segments of frames 1, 2, 3, 4, . . . are extracted from a digital audio signal. The frames 1, 2, 3, 4, . . . are unit frames that are the same in length, and the adjacent frames overlap in, for example, half of the unit frame. In FIG. 15, the digital audio signal includes data samples x₀, x₁, x₂, x₃, . . . , xₙ.

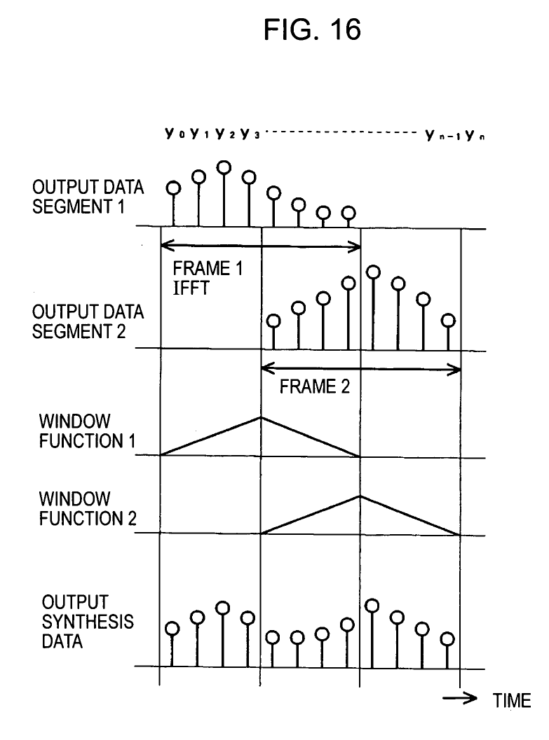

When the digital audio signal is subjected to the sound-source separation and inverse FFT processing described in the foregoing embodiments, the resulting time-series data (y₀, y₁, y₂, y₃, . . . , yₙ) shown in FIG. 16 also has overlapping frames, such as output data segments 1 and 2.

Thereafter, according to the eighth embodiment, as shown in FIG. 16, triangular window functions 1 and 2 shown in FIG. 16 are applied to adjacent output data segments whose frames overlap each other, e.g., output data segments 1 and 2, and synchronous data points in the overlapping frames of the output data segments 1 and 2 are summed to obtain output synthesis data shown in FIG. 16. The separated output audio signal is free of discontinuous waveform at frame boundaries, or is noise-free.

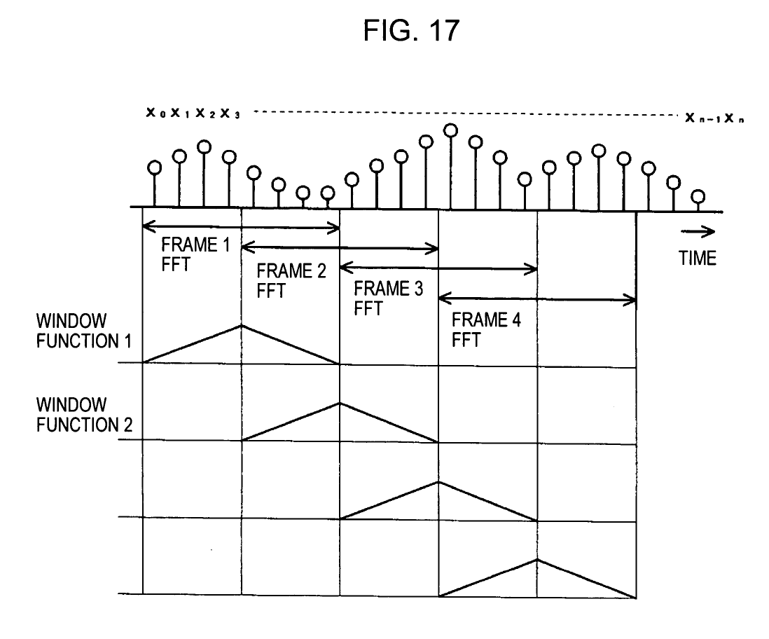

According to a ninth embodiment of the present invention, as shown in FIG. 17, data segments are extracted so that predetermined frames of adjacent data segments, e.g., frames 1, 2, 3, and 4, overlap each other, and triangular window functions 1, 2, 3, and 4 shown in FIG. 17 are applied to the extracted data segments of the frames 1, 2, 3, and 4 before performing FFT processing.

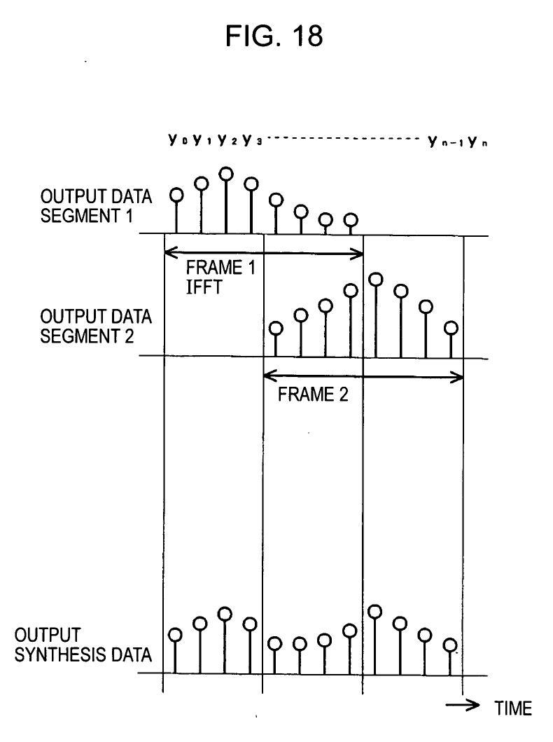

After applying the window functions 1, 2, 3, and 4 shown in FIG. 17, FFT processing is performed. When the signal subjected to appropriate sound-source separation processing is transformed using inverse FFT, output data segments 1 and 2 shown in FIG. 18 are produced. The output data segments 1 and 2 are window-processed data segments in which window functions have been applied to the overlapping frame portion. It is therefore only required for an output section to sum the overlapping data segments to produce a noise-free separated audio signal whose waveform is not discontinuous at frame boundaries.

In addition to a triangular window function, other window functions, such as a Hanning window function, a Hamming window function, and a Blackman window function, may be used.

In the foregoing embodiments, a time-discrete signal is transformed into a frequency-domain signal using orthogonal transform, and frequency spectra of stereo channels are compared. In principle, a signal may be segmented in the time domain by multiple band-pass filters, and similar processing may be performed for each frequency band. However, FFT processing as in the foregoing embodiments is more practical because it is easy to increase the frequency resolution and to improve the source-separation performance.

While the foregoing embodiments have been described in the context of two-channel stereo signals as two audio signals, any type of two audio signals may be used as long as an audio signal of a sound source is distributed in these two audio signals by a predetermined level ratio or level difference. The same applies to the phase difference.

In the foregoing embodiments, the level ratios of two audio signals between the frequency spectra are determined, and a multiplication factor generator sets a function of the level ratio versus the multiplication factor. The level differences of two audio signals between the frequency spectra may be determined, and the multiplication factor generator may use a function of the level difference versus the multiplication factor.

An orthogonal transformer for transforming a time-series signal into a frequency-domain signal is not limited to an FFT processor, and any transformer capable of comparing the levels or phases of the frequency spectra may be used.

It should be understood by those skilled in the art that various modifications, combinations, sub-combinations and alterations may occur depending on design requirements and other factors insofar as they are within the scope of the appended claims or the equivalents thereof.

What is claimed is:

1. An audio signal processing apparatus comprising:
dividing means for dividing each of two audio signals into a plurality of frequency bands;
level comparing means for determining a level ratio or level difference between the two audio signals in each of the plurality of frequency bands divided by the dividing means; and
output control means for controlling an output of the dividing means according to the level ratio or level difference determined by the level comparing means.

2. An audio signal processing apparatus comprising:
first transform means for transforming a first time-series audio signal of two time-series audio signals into a first frequency-domain signal;
second transform means for transforming a second time-series audio signal of the two time-series audio signals into a second frequency-domain signal;
level determining means for determining a level ratio or level difference between a frequency spectrum of the first frequency-domain signal obtained from the first transform means and a frequency spectrum of the second frequency-domain signal obtained from the second transform means; and
output control means for controlling and outputting a level of the frequency spectrum obtained from at least one of the first transform means and the second transform means based on the level ratio or level difference determined by the level determining means.

3. The audio signal processing apparatus according to claim 2, further comprising inverse transform means for transforming the frequency-domain signal from the output control means into a time-series signal.

4. The audio signal processing apparatus according to claim 2, further comprising phase difference determining means for determining a phase difference between a frequency spectrum of the first frequency-domain signal obtained from the first transform means and a frequency spectrum of the second frequency-domain signal obtained from the second transform means,
wherein the output control means controls and outputs a level of the frequency spectrum obtained from at least one of the first transform means and the second transform means based on the level ratio or level difference determined by the level determining means and the phase difference determined by the phase difference determining means.

5. The audio signal processing apparatus according to claim 4, further comprising inverse transform means for transforming the frequency-domain signal from the output control means into a time-series signal.

6. The audio signal processing apparatus according to claim 2, wherein the output control means includes:
a multiplication factor generation section generating a multiplication factor that is set as a function of the level ratio or level difference determined by the level determining means; and
a sound source separation section multiplying the frequency spectrum obtained from at least one of the first transform means and the second transform means by the multiplication factor generated by the multiplication factor generation section, and determining an output level of the frequency spectrum.

7. The audio signal processing apparatus according to claim 4, wherein the output control means includes:
a multiplication factor generation section generating a multiplication factor that is set as a function of the phase difference determined by the phase difference determining means; and
a sound source separation section multiplying the frequency spectrum obtained from at least one of the first transform means and the second transform means by the multiplication factor generated by the multiplication factor generation section, and determining an output level of the frequency spectrum.

8. The audio signal processing apparatus according to claim 3, wherein the output control means includes:
a plurality of multiplication factor generation sections generating multiplication factors that are set as functions of the level ratio or level difference determined by the level determining means; and
a plurality of sound source separation sections each multiplying the frequency spectrum obtained from at least one of the first transform means and the second transform means by each of the multiplication factors generated by the multiplication factor generation sections and determining an output level of the frequency spectrum, and
the inverse transform means includes a plurality of inverse transform sections transforming outputs from the plurality of sound source separation sections into time-series signals.

9. The audio signal processing apparatus according to claim 2, wherein the output control means includes:
a plurality of multiplication factor generation sections generating multiplication factors that are set as functions of the level ratio or level difference determined by the level determining means;
a selection section selecting one of the multiplication factors generated by the plurality of multiplication factor generation sections; and
a sound source separation section multiplying the frequency spectrum obtained from at least one of the first transform means and the second transform means by the multiplication factor selected by the selection section and determining an output level of the frequency spectrum.

10. The audio signal processing apparatus according to claim 2, further comprising detecting means for detecting the frequency of the maximum level in the output spectrum from the output control means and outputting the detected frequency as output data.

11. The audio signal processing apparatus according to claim 6, wherein a multiplication factor for a frequency spectrum whose level ratio or level difference determined by the level determining means is outside a predetermined range is set to 0.

12. The audio signal processing apparatus according to claim 3, further comprising:
segmenting means for segmenting the two time-series audio signals into predetermined frames to produce data segments so that the adjacent data segments overlap each other in a portion of the frames, and supplying the data segments to the first transform means and the second transform means; and
outputting means for applying a window function to the data segments corresponding to the output time-series signal from the inverse transform means, summing synchronous data segments in the output time-series signal, and outputting the resulting time-series signal.

13. The audio signal processing apparatus according to claim 3, further comprising:
segmenting means for segmenting the two time-series audio signals into predetermined frames to produce data segments so that the adjacent data segments overlap each other in a portion of the frames, applying a window function to the data segments, and supplying the data segments to the first transform means and the second transform means; and
outputting means for summing synchronous data segments in the output time-series signal from the inverse transform means and outputting the resulting time-series signal.

14. An audio signal processing method comprising the steps of:
dividing each of two audio signals into a plurality of frequency bands;
determining a level ratio or level difference between the two audio signals in each of the plurality of divided frequency bands; and
controlling an output of the divided audio signals according to the level ratio or level difference determined in the step of determining a level ratio or level difference.

15. An audio signal processing method comprising the steps of:
transforming two time-series audio signals into frequency-domain signals to produce two frequency spectra;
determining a level ratio or level difference between the two frequency spectra produced in the step of transforming two time-series audio signals; and
controlling and outputting a level of at least one frequency spectrum of the two frequency spectra produced in the step of transforming two time-series audio signals based on the level ratio or level difference determined in the step of determining a level ratio or level difference.

16. The audio signal processing method according to claim 15, further comprising a step of transforming the frequency-domain signal obtained in the step of controlling and outputting a level into a time-series signal.

17. The audio signal processing method according to claim 15, further comprising a step of determining a phase difference of the two time-series audio signals between the frequency spectra produced in the step of transforming two time-series audio signals,
wherein the step of controlling and outputting a level controls and outputs a level of at least one frequency spectrum of the two frequency spectra produced in the step of transforming two time-series audio signals based on the level ratio or level difference determined in the step of determining a level ratio or level difference and the phase difference determined in the step of determining a phase difference.

18. The audio signal processing method according to claim 17, further comprising a step of transforming the frequency-domain signal obtained in the step of controlling and outputting a level into a time-series signal.

19. The audio signal processing method according to claim 15, further comprising a step of detecting the frequency of the maximum level in the output spectrum obtained in the step of controlling and outputting a level to output the detected frequency as output data.

20. An audio signal processing apparatus comprising:
a dividing unit dividing each of two audio signals into a plurality of frequency bands;
a level comparing unit determining a level ratio or level difference between the two audio signals in each of the plurality of frequency bands divided by the dividing unit; and
an output control unit controlling an output of the dividing unit according to the level ratio or level difference determined by the level comparing unit.

21. An audio signal processing apparatus comprising:
a first transform unit transforming a first time-series audio signal of two time-series audio signals into a first frequency-domain signal;
a second transform unit transforming a second time-series audio signal of the two time-series audio signals into a second frequency-domain signal;
a level determining unit determining a level ratio or level difference between a frequency spectrum of the first frequency-domain signal obtained from the first transform unit and a frequency spectrum of the second frequency-domain signal obtained from the second transform unit; and
an output control unit controlling and outputting a level of the frequency spectrum obtained from at least one of the first transform unit and the second transform unit based on the level ratio or level difference determined by the level determining unit.
